(19) United States
(12) Patent Application Publication
(10) Pub. No.: US 2009/0218045 A1
(43) Pub. Date: Sep. 3, 2009

(54) PLASMA PROCESSING APPARATUS

(76) Inventors: Mitsuru Hiroshima, Osaka (JP); Hiromi Asakura, Hyogo (JP); Syouzou Watanabe, Osaka (JP); Mitsuhiro Okune, Osaka (JP); Hiroyuki Suzuki, Osaka (JP); Ryuzou Houchin, Osaka (JP)

Correspondence Address: WENDEROTH, LIND & PONACK L.L.P., 1030 15th Street, N.W., Suite 400 East, Washington, DC, 20005-1503, US

(21) Appl. No.: 12/092,381

(22) PCT Filed: Nov. 1, 2006
(86) PCT No.: PCT/JP2006/321890

§ 371 Date: Feb. 6, 2009

(30) Foreign Application Priority Data
Nov. 2, 2005 (JP) 2005-319575
Nov. 15, 2005 (JP) 2005-329756
Oct. 6, 2006 (JP) 2006-275409
Oct. 30, 2006 (JP) 2006-294334

(51) Int. Cl. C23F 1/08; C23C 16/54

(52) U.S. Cl. 156/345.48; 118/723 I

(57) ABSTRACT

The plasma processing apparatus has a beam-shaped spacer 7 placed at the upper opening of the chamber 3 opposed to the substrate 2. The beam-shaped spacer 7 has an annular outer peripheral portion 7a whose lower surface 7d is supported by the chamber 3, a central portion 7b located at the center of a region surrounded by the outer peripheral portion 7a in plane view, and a plurality of beam portions 7c extending radially from the central portion 7b to the outer peripheral portion 7a. An entire of a dielectric plate 8 is uniformly supported by the beam-shaped spacer 7. The dielectric plate 8 can be reduces in thickness while securing a mechanical strength for supporting the atmospheric pressure when the chamber 3 is internally reduced in pressure.

### TECHNICAL FIELD

The present invention relates to plasma processing apparatuses such as dry etching apparatuses, plasma CVD apparatuses and so on.

### BACKGROUND ART

Regarding a plasma processing apparatus of an induction coupling plasma (ICP) type, it is one of known construction that an upper part of a chamber is closed with a dielectric plate and a coil to which a high-frequency power is applied is arranged on the dielectric plate. Since the chamber is internally reduced in pressure, the dielectric plate needs to have a thickness of a certain degree in order to secure a mechanical strength for supporting the atmospheric pressure. However, the thicker the thickness of the dielectric plate is, the larger the loss of the high-frequency power applied from the coil to the plasma becomes. In detail, the loss of applied high-frequency power is large when the thickness of the dielectric plate is thick, and therefore, a high-frequency power source of a large capacity is needed to generate high-density plasma. Since the loss of applied power is transformed into heat, the quantity of heat increases in accordance with an increase in the capacity of the high-frequency power source, and temperature rises in the dielectric plate and the peripheral components become significant. As a result, when the number of substrates to be processed is increased, changes occur in the process characteristics such as etching rate, shape and so on.

In contrast to this, for example, JP H10-27782 A (Publication 1) and JP 2001-110777 A (Publication 2) disclose plasma processing apparatuses in which the dielectric plate is reduced in thickness while securing the mechanical strength by supporting the lower surface side of the dielectric plate with a beam-shaped structure.

However, the conventionally proposed structures that support the dielectric plate, including those disclosed in the Publications 1 and 2, take no consideration for the reduction of the loss of the applied high-frequency power due to the deformation of the dielectric plate when the chamber is internally reduced in pressure and the existence of the beam-shaped structure.

The gases introduced into the chamber in the plasma processing apparatus can be categorized roughly into a process gas (e.g., etching gas that supplies radicals and ions for etching in the case of, for example, a dry etching apparatus) and a carrier gas for maintaining electric discharge. In general, the energy necessary for the plasmatization of the etching gas is smaller than that necessary for the plasmatization of the carrier gas. Therefore, if the etching gas and the carrier gas are introduced from an identical place into the chamber and made to simultaneously pass through an intense magnetic field generated by a coil or the like, then the etching gas is excessively dissociated (radicalized) and ionized, while the carrier gas is insufficiently dissociated and ionized.

In contrast to this, JP 3384795 (Publication 3) discloses a plasma processing apparatus in which the excessive dissociation and ionization of the etching gas are suppressed by providing different positions of introducing the etching gas and the carrier gas into the chamber. Specifically, in the plasma processing apparatus disclosed in the Publication 3, the carrier gas is introduced from a plurality of bleed holes formed at a dielectric plate close to the upper part of the chamber, and the etching gas is introduced from a metal pipe placed in between the dielectric plate and a lower electrode on which the substrate is placed.

However, the structure of Publication 3 has a complicated structure in view of that a plurality of bleed holes and flow passages for connecting these bleed holes to a gas source need to be formed in the dielectric plate, that the metal pipe for introducing the etching gas is necessary, and so on. Moreover, according to the structure of the Publication 3, it is difficult to increase the size of the apparatus in order to enable the processing of a large-scale substrate. In detail, the dielectric plate needs to have a sufficient mechanical strength to support the atmospheric pressure when the chamber is reduced in pressure. However, in the apparatus of the Publication 3, the dielectric plate, at which the bleed holes and the flow passages are formed, is supported by the main body of the chamber merely at an adjacency of its outer peripheral edge. Therefore, it is difficult to secure the required mechanical strength when the dielectric plate is increased in size.

Moreover, a certain process condition requires to attach more importance to the uniformization of the etching process by controlling the flow rate distribution of the etching gas in the surroundings of the substrate than to the rationalization of the dissociation and ionization of the etching gas.

### DISCLOSURE OF INVENTION

### Problem to be Solved by the Invention

A first object of the present invention is to reduce a thickness of a dielectric plate while securing a mechanical strength in consideration of deformation of the dielectric plate when the chamber is internally reduced in pressure and to reduce the loss of applied high-frequency power due to the existence of a beam-shaped structure in a plasma processing apparatus.

A second object of the present invention is to provide a plasma processing apparatus that can achieve uniformization of plasma processing by preferable processing where excessive dissociation and ionization of the process gas are suppressed and by control of the flow rate distribution of the process gas in the surroundings of the substrate, with a structure that is relatively simple and can be increased in size.

### Means for Solving the Problem

In order to achieve the first object, the present invention provides a plasma processing apparatus, comprising a vacuum vessel (3) in which a substrate (2) is placed, a beam-shaped structure (7) placed at an upper opening of the vacuum vessel opposed to the substrate and provided with an annular outer peripheral portion (7a) a lower surface (7d) of which is supported by the vacuum vessel, a central portion (7b) located at a center of a region surrounded by the outer peripheral portion in plane view, and a plurality of beam portions (7c) which extend radially from the central portion to the outer peripheral portion, a region surrounded by the outer peripheral portion, the central portion and the beam portions constituting a window portions (26), a dielectric plate (8) a lower surface (8a) of which is supported by an upper surface (7g) of the beam-shaped structure; and a coil (9) for generating plasma which is placed on an upper surface side of the dielectric plate and to which a high-frequency power is applied.

The beam-shaped structure has the annular outer peripheral portion, the central portion located at the center of the region surrounded by the outer peripheral portion, and the plurality of beam portions that extend radially from the central portion to the outer peripheral portion. With this arrangement, all the portions, i.e., the outer peripheral portion, the central portion, and the portion intermediate between the outer peripheral portion and the central portion, of the dielectric plate are supported by the beam-shaped structure. In other words, an entire of the dielectric plate is uniformly supported by the beam-shaped structure. When the vacuum vessel is reduced in pressure, the central portion of the dielectric plate easily sags downward. The beam-shaped structure has the central portion connected with the outer peripheral portion by the beam portions, and the central portion supports the central portion of the dielectric plate from the lower surface side. Therefore, the sag of the central portion of the dielectric plate can be effectively prevented or suppressed. For the above reasons, the dielectric plate can be reduced in thickness while securing a mechanical strength (also in consideration of the deformation of the dielectric plate when the vacuum vessel is internally reduced in pressure) to support the atmospheric pressure when the vacuum vessel is internally reduced in pressure. Since the loss of applied high-frequency power can be largely reduced by reducing the thickness of the dielectric plate, the plasma can be densified. Moreover, since the high-frequency power applied to the coil can be reduced by densifying the plasma, change of the process characteristics such as etching rate, etching shape and so on in accordance with an increase in the number of substrates to be processed due to the heat generation of the dielectric plate and so on can be prevented.

In order to accomplish the second object, it is preferred that the plasma processing apparatus of the present invention further comprising a first gas inlet port (31) formed at the outer peripheral portion of the beam-shaped structure and obliquely downwardly ejecting a gas, a second gas inlet port (34) formed at the central portion of the beam-shaped structure and downwardly ejecting a gas toward the central portion of the substrate, a carrier gas supply source (20) capable of ejecting a carrier gas from at least one of the first and second gas inlet ports, and a process gas supply source (19′) capable of ejecting a process gas from at least one of the first and second gas inlet ports.

For example, the carrier gas supply source ejects the carrier gas from the first gas inlet port whereas the process gas supply source ejects the process gas from the second gas inlet port.

By applying the high-frequency power to the coil, intense magnetic fields (intense alternating electric fields) are formed at the window portions of the beam-shaped structure. The carrier gas, which is obliquely downwardly ejected from the first gas inlet port formed at the outer peripheral portion of the beam-shaped structure, therefore passes through the intense magnetic fields. As a result, the carrier gas is sufficiently dissociated or ionized. On the other hand, the process gas, which is downwardly ejected from the second gas inlet port formed at the central portion of the beam-shaped structure toward the central portion of the substrate, does therefore not pass through the intense magnetic fields formed at the window portions. Therefore, neither excessive dissociation nor ionization of the process gas occurs. This results in that excessive dissociation and ionization of the process gas can be suppressed while sufficiently dissociating or ionizing the carrier gas, and satisfactory plasma processing can be achieved. For example, in a case where the process gas is the etching gas, by suppressing the excessive dissociation and ionization of the etching gas while sufficiently dissociating or ionizing the carrier gas, a ratio between the radicals and ions can be individually controlled according to the kind of the gas, i.e., with regard to each of the etching gas and the carrier gas, and therefore, an etching process of which the etching rate and selection ratio are satisfactory can be achieved. Moreover, the structures of the first and the second gas inlet ports are relatively simple in the arrangement that both of them are provided at the beam-shaped structure and in the arrangement that neither gas inlet port nor the like needs to be provided for the dielectric plate itself.

As an alternative, the process gas supply source ejects the process gas from the first gas inlet port whereas the carrier gas supply source ejects the carrier gas from the second gas inlet port.

By obliquely downwardly ejecting the process gas from the first gas inlet port formed at the outer peripheral portion of the beam-shaped structure, the process gas can be densely plasmatized. Moreover, the carrier gas can be ejected from the second gas inlet port, and the gas flow rate distribution at the center of the substrate can be changed without increasing or decreasing the flow rate of the process gas that contributes to the etching characteristics such as etching rate, etching shape and so on. As a result, the plasma processing of the substrate can be uniformized. For example, in a case where the process gas is the etching gas, a uniform etching process free of nonuniformity in the etching rate and so on can be performed on the entire substrate. It should be note that that the statement of “without increasing or decreasing the flow rate of the process gas” does not mean elimination of an increase or decrease in the flow rate of the process gas to an extent that no bad influence is exerted on the etching characteristics.

### EFFECT OF THE INVENTION

In the plasma processing apparatus of the present invention, the dielectric plate is supported by the beam-shaped structure that has the annular outer peripheral portion, the central portion located at the center of the region surrounded by the outer peripheral portion and the plurality of beam portions that extend radially from the central portion to the outer peripheral portion. Therefore, the dielectric plate can be reduced in thickness while securing the mechanical strength also in consideration of the deformation of the dielectric plate when the vacuum vessel is internally reduced in pressure. Since the loss of the applied high-frequency power can be largely reduced by reducing the thickness of the dielectric plate, the plasma can be densified. Moreover, since the high-frequency power applied to the coil can be reduced by densifying the plasma, change of the process characteristics such as etching rate, etching shape and so on in accordance with an increase in the number of substrates to be processed due to the heat generation of the dielectric plate and so on can be prevented.

By enabling the carrier gas to be ejected by the carrier gas supply source from at least one of the first gas inlet port formed at the outer peripheral portion of the beam-shaped structure and the second gas inlet port formed at the central portion of the beam-shaped structure and enabling the process gas to be ejected by the process gas supply source from at least one of the first and second gas inlet ports, satisfactory plasma processing can be achieved by individually controlling the dissociation and ionization of the process gas in accordance with the kind of the gas. Otherwise, by changing the gas flow rate distribution at the center of the substrate without increasing or reducing the process gas that contributes to the etching characteristics such as etching rate, etching shape and so on, the plasma processing of the substrate can be uniformized. Moreover, the structure is relatively simple, and an increase in the size of the apparatus can also be achieved.

### BRIEF DESCRIPTION OF THE DRAWINGS

These and other aspects and features of the present invention will become clear from the following description taken in conjunction with the preferred embodiments thereof with reference to the accompanying drawings, in which:

FIG. 1 is a schematic sectional view of a dry etching apparatus according to a first embodiment of the present invention;

FIG. 2 is a sectional view taken along the line II-II of FIG. 1;

FIG. 3 is a plan view showing an ICP coil;

FIG. 4A is a schematic plan view showing a beam-shaped spacer and the ICP coil;

FIG. 4B is a schematic plan view showing an alternative of the ICP coil;

FIG. 5A is a schematic plan view showing an alternative of the beam-shaped spacer;

FIG. 5B is a schematic plan view showing another alternative of the beam-shaped spacer;

FIG. 5C is a schematic plan view showing yet another alternative of the beam-shaped spacer;

FIG. 6 is a partially enlarged view of the portion VI of FIG. 1;

FIG. 7 is a partially enlarged view of the portion VII of FIG. 1;

FIG. 8 is a perspective view of an inlet port plate;

FIG. 9A is a perspective view of an inlet port plate for replacement;

FIG. 9B is a perspective view of another inlet port plate for replacement;

FIG. 10 is a partially enlarged view of FIG. 1 for explaining a gas flow rate;

FIG. 11 is a partially enlarged view of FIG. 1 for explaining the gas flow rate when the inlet port plate is replaced;

FIG. 12 is a schematic perspective view of a beam-shaped spacer provided for a dry etching apparatus according to a second embodiment of the present invention;

FIG. 13 is a partially enlarged sectional view showing a dry etching apparatus according to a third embodiment of the present invention;

FIG. 14 is an arrow view taken along the arrow XIV of FIG. 13;

FIG. 15 is a partially enlarged sectional view showing an alternative of the cover;

FIG. 16 is a partial sectional view showing a beam-shaped spacer provided for a dry etching apparatus according to a fourth embodiment of the present invention;

FIG. 17 is a perspective view showing a partition member;

FIG. 18 is a partial sectional view showing a beam-shaped spacer provided for a dry etching apparatus according to a fifth embodiment of the present invention;

FIG. 19 is a perspective view showing an inlet port chip;

FIG. 20 is a partial sectional view of a beam-shaped spacer having an inlet port chip of an alternative;

FIG. 21 is a perspective view showing an inlet port chip of an alternative;

FIG. 22 is a schematic sectional view of a dry etching apparatus according to a sixth embodiment of the present invention;

FIG. 23 is a plan view showing a beam-shaped spacer of the sixth embodiment;

FIG. 24 is a schematic perspective view of the beam-shaped spacer of the sixth embodiment viewed from the bottom surface side;

FIG. 25 is a schematic sectional view of a dry etching apparatus according to a seventh embodiment of the present invention;

FIG. 26 is a schematic sectional view of a dry etching apparatus according to an eighth embodiment of the present invention;

FIG. 27 is a schematic sectional view of a dry etching apparatus according to a ninth embodiment of the present invention;

FIG. 28 is a sectional view taken along the line XXVIII-XXVIII of FIG. 1; and

FIG. 29 is a schematic sectional view of a dry etching apparatus according to a tenth embodiment of the present invention.

### DETAILED DESCRIPTION OF THE INVENTION

### Best Mode for Carrying out the Invention

### First Embodiment

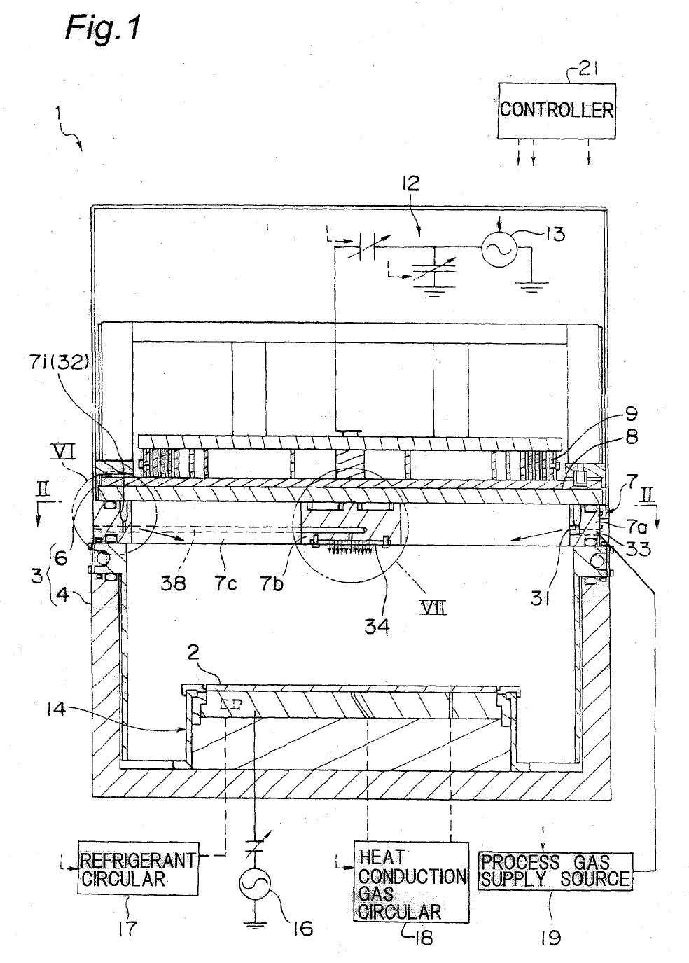

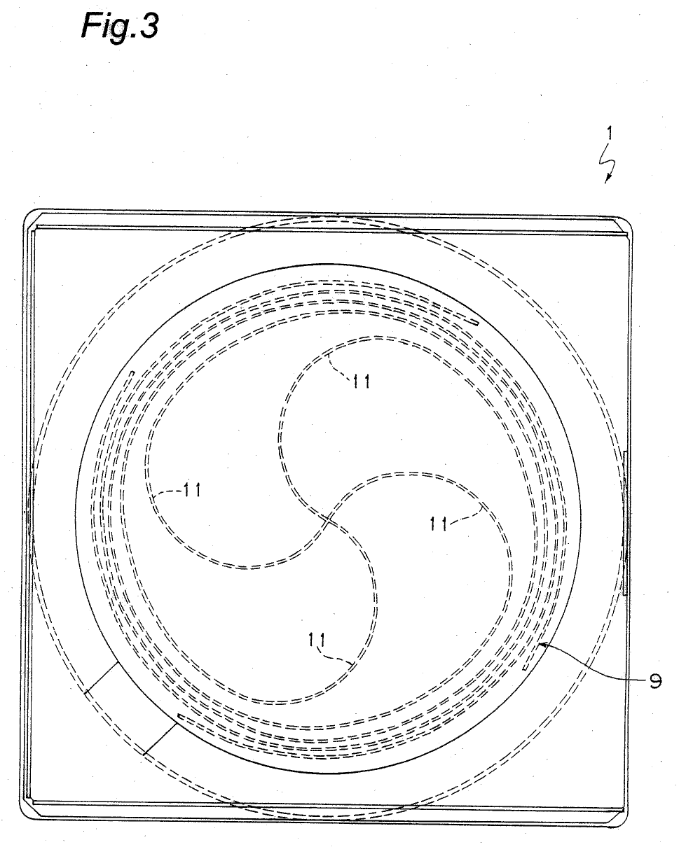

FIG. 1 shows a dry etching apparatus 1 of ICP (Induction Coupling Plasma) type according to an embodiment of the present invention. The dry etching apparatus 1 has a chamber (vacuum vessel) 3 that constitutes a processing chamber in which a substrate 2 is received. The chamber 3 has a chamber main body 4 whose upper part is opened, and a lid 6 that seals the upper opening of the chamber main body 4. The lid 6 has a beam-shaped spacer (beam-shaped structure) 7 supported by the upper end of the sidewall of the chamber main body 4, and a disk-shaped dielectric plate 8 that functions as a top plate supported by the beam-shaped spacer 7. In the present embodiment, the beam-shaped spacer 7 is made of a metal material of aluminum, stainless steel (SUS) or the like having a sufficient rigidity, and the dielectric plate 8 is made of yttrium oxide (Y₂O₃). The beam-shaped spacer 7 may undergo surface treatment for improving the wear resistance such as yttrium oxide thermal spraying or the like. An ICP coil 9 is provided on the dielectric plate 8. As shown in FIG. 3, the ICP coil 9 is constructed of a plurality of (four in the present embodiment) conductors 1 that extend spirally from the center toward the outer periphery of the dielectric plate 8 in plane view. At a portion (turn starting portion) corresponding to the center of the dielectric plate 8 in plane view, an interval between adjoining conductors 1 is large. In other words, the turn density of the conductors 1 is coarse in the portion corresponding to the center of the dielectric plate 8. In contrast to this, in a portion corresponding to the outer periphery of the dielectric plate 8 in plane view, an interval between adjoining conductors 1 is narrow, and the turn density is dense. A high-frequency power source 13 is electrically connected to the ICP coil 9 via a matching circuit 12. It is noted that a gate (not shown) for loading and unloading the substrate 2 is provided at the chamber main body 4.

A substrate susceptor 14 that has a function as a lower electrode to which a bias voltage is applied and a function to retain the substrate 2 by electrostatic attraction or the like is provided on the bottom side in the chamber 3 opposed to the dielectric plate 8 and the beam-shaped spacer 7. A high-frequency power is applied to the substrate susceptor 14 from a high-frequency power source 16 for biasing. Moreover, a refrigerant circulation passage is provided in the substrate susceptor 14, and a temperature-controlled refrigerant supplied from a refrigerant circulator 17 circulates in the circulation passage. Further, a heat conduction gas circulator 18 that supplies a heat conduction gas to a minute gap between the upper surface of the substrate susceptor 14 and the back surface of the substrate 2 is provided.

The chamber 3 is internally evacuated by an evacuator (not shown), and a process gas is introduced from a process gas supply source 19 via gas inlet ports 31 and 34 described later. Subsequently, a high-frequency power is applied to the ICP coil 9 from the high-frequency power source 13, and plasma is generated to be maintained in the chamber 3. As described in detail later, the surface of the substrate 2 is etched by the operation of the radicals and ions of the etching gas generated by the plasma. The operation of the whole apparatus including the high-frequency power sources 13 and 16, process gas supply source 19, heat conduction gas circulator 18 and refrigerant circulator 17 is controlled by a controller 21.

Referring to FIGS. 1, 2 and 4A, the beam-shaped spacer 7 of the present embodiment has an annular outer peripheral portion 7a, a central portion 7b located at the center of a region surrounded by the outer peripheral portion 7a in plane view, and a plurality of (six in the present embodiment) beam portions 7c that extend radially from the central portion 7b to the outer peripheral portion 7a.

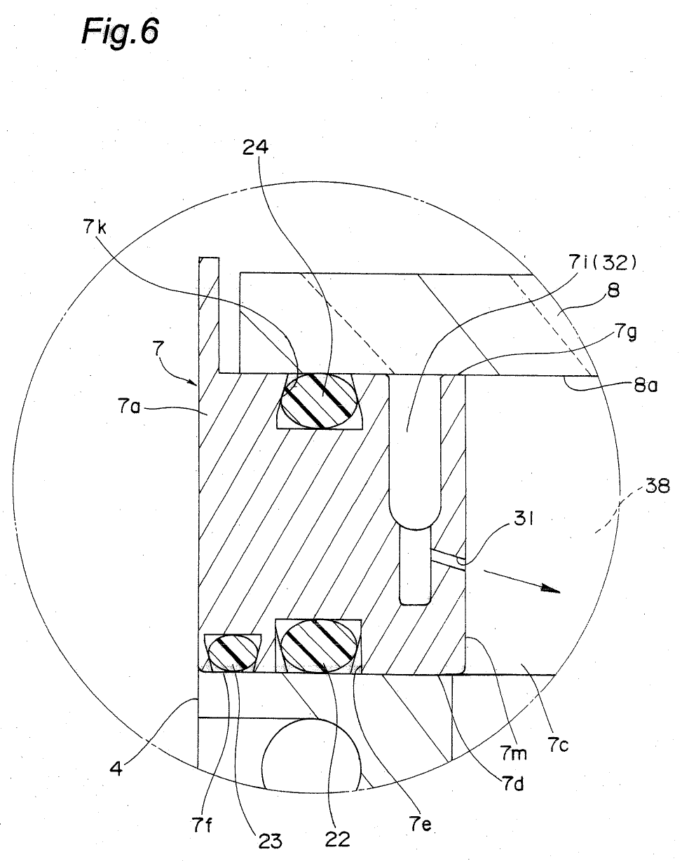

With reference also to FIG. 6, a lower surface 7d of the outer peripheral portion 7a of the beam-shaped spacer 7 is supported on the upper end surface of the sidewall of the chamber main body 4. Annular grooves 7e and 7f are formed on the lower surface 7d of the outer peripheral portion 7a, and the sealability of a juncture between the beam-shaped spacer 7 and the chamber main body 4 is secured by O-rings 22 and 23 received in the grooves 7e and 7f.

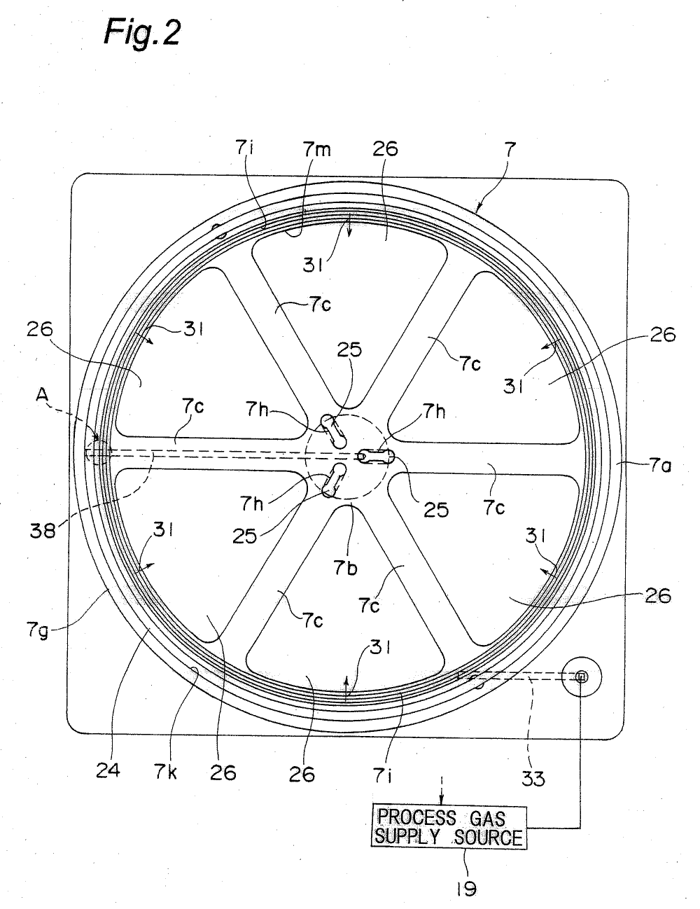

As clearly shown in FIGS. 2, 4A and 6, an annular groove 7k is formed also on an upper surface 7g of the outer peripheral portion 7a, and an O-ring (first elastic member) 24 is received in the groove 7k. The O-ring 24 is interposed between the outer peripheral portion 7a of the beam-shaped spacer 7 and a lower surface 8a of the dielectric plate 8. In other words, the outer peripheral portion 7a of the beam-shaped spacer 7 is put in indirect contact with the dielectric plate 8 via the O-ring 24. The O-ring 24 has an additional function to secure airtightness at a juncture between the beam-shaped spacer 7 and the dielectric plate 8.

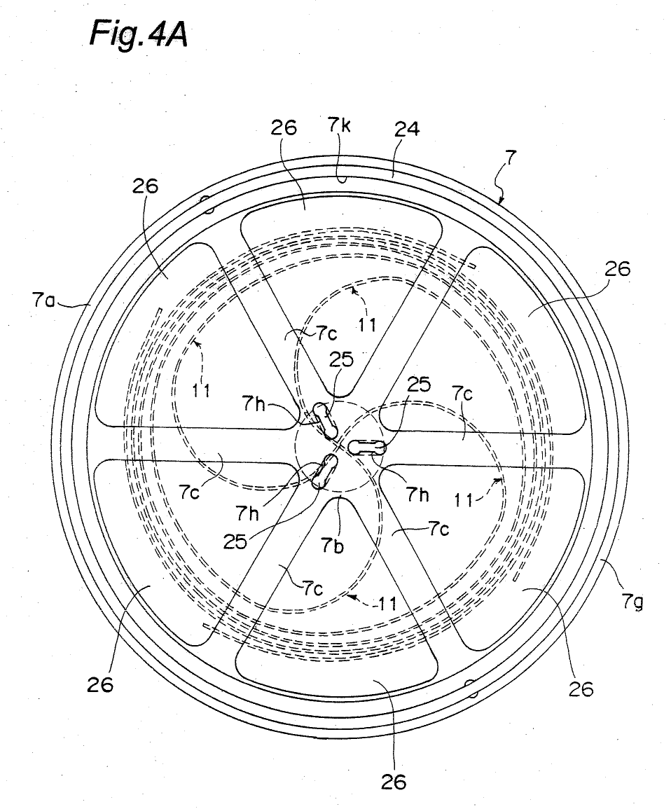

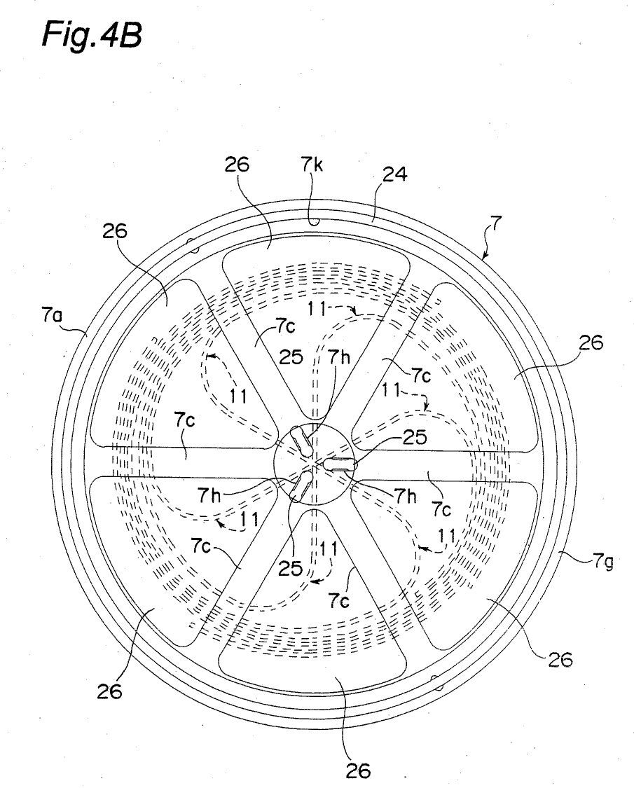

The six beam portions 7c of the beam-shaped spacer 7 have a rectangular shape of an almost constant width and extend radially from the central portion 7b at equiangular intervals in plane view (see FIGS. 2 and 4A). One end of the beam portions 7c is integrally connected with the central portion 7b, and the other end is integrally connected with the outer peripheral portion 7a. Moreover, as shown in FIGS. 4A and 4B, the six beam portions 7c extend in a direction perpendicular to a portion, in which the turn density corresponding to the outer periphery of the dielectric plate 8 is dense in plane view, of the four spiral strip-shaped conductors 1 that constitute the ICP coil 9 in plane view.

As shown in FIG. 4A, three recess portions 7h are provided on the upper surface 7g at the central portion 7b of the beam-shaped spacer 7, and an elastic member (second elastic member) 25 is received in each of the recess portions 7h. The elastic member 25 is interposed between the central portion 7b of the beam-shaped spacer 7 and the lower surface 8a of the dielectric plate 8. In other words, the central portion 7b of the beam-shaped spacer 7 is put in indirect contact with the dielectric plate 8 via the elastic members 25.

Regions respectively surrounded by the outer peripheral portion 7a, the central portion 7b and the beam portions 7c of the beam-shaped spacer 7 constitutes window portions 26 from which the lower surface 8a of the dielectric plate 8 is exposed when viewed from the substrate susceptor 14 side. In the present embodiment, the beam-shaped spacer 7 has six window portions 26, each of which has a sectoral shape.

As described above, the beam-shaped spacer 7 has the annular outer peripheral portion 7a, the central portion 7b located at the center of the region surrounded by the outer peripheral portion 7a, and the plurality of beam portions 7c that extend radially from the central portion 7b to the outer peripheral portion 7a. Therefore, all portions of the lower surface 8a of the dielectric plate 8, i.e., the outer peripheral portion, the central portion, and the portion located between the outer peripheral portion and the central portion are supported by the beam-shaped spacer 7. In other words, an entire of the dielectric plate 8 is uniformly supported by the beam-shaped spacer 7. When the chamber 3 is internally reduced in pressure, a differential pressure between the internal pressure (negative pressure) of the chamber and the atmospheric pressure takes effect on the dielectric plate 8. However, the entire of the dielectric plate 8 is uniformly supported by the beam-shaped spacer 7 even when a load due to the differential pressure takes effect. On the other hand, particularly the central portion of the dielectric plate 8 easily sags downward (toward the substrate susceptor 14 side) by the load due to the differential pressure when the chamber 3 is internally reduced in pressure. The beam-shaped spacer 7 has the central portion 7b connected to the outer peripheral portion 7a with the beam portions 7c, and the central portion 7b supports the central portion of the dielectric plate 8 from the lower surface 8a side. Therefore, the sag of the central portion of the dielectric plate 8 can be effectively prevented or suppressed.

As described above, by uniformly supporting the lower surface of the dielectric plate 8 by the beam-shaped spacer 7 and supporting the central portion of the dielectric plate 8 that easily sags by the central portion 7b of the beam-shaped spacer 7, the dielectric plate 8 can be reduced in thickness while securing the mechanical strength (also in consideration of the deformation of the dielectric plate 8 when the chamber 3 is internally reduced in pressure) to support the atmospheric pressure when the chamber 3 is internally reduced in pressure. For example, when a dielectric plate of a diameter of 320 mm is supported by a spacer that supports only the outer peripheral portion of the dielectric plate, the thickness of the dielectric plate needs to be set to 25 mm or more in order to secure the mechanical strength. In contrast to this, when the dielectric plate 8 of a diameter of 320 mm is supported by the beam-shaped spacer 7 of the present embodiment, the required mechanical strength can be obtained when the dielectric plate 8 has a thickness of approximately 10 mm. Since the loss of the applied high-frequency power can be remarkably reduced by reducing the thickness of the dielectric plate 8, the plasma can be densified. Moreover, since the high-frequency power applied to the ICP coil 9 can be reduced by densifying the plasma, changing of the process characteristics such as etching rate, etching shape and so on in accordance with an increase in the number of substrates to be processed due to the heat generation of the dielectric plate and so on can be prevented.

As described above, the O-ring 24 is interposed between the outer peripheral portion 7a of the beam-shaped spacer 7 and the outer peripheral portion of the lower surface 8a of the dielectric plate 8. Therefore, damage and breakage of the dielectric plate 8 due to the direct contact of the outer peripheral portion of the lower surface 8a of the dielectric plate 8 with the outer peripheral portion 7a of the beam-shaped spacer 7 can be prevented. Likewise, the elastic member 25 is interposed between the central portion 7b of the beam-shaped spacer 7 and the central portion of the lower surface 8a of the dielectric plate 8. Therefore, damage and breakage of the dielectric plate 8 due to the direct contact of the lower surface 8a of the dielectric plate 8 with the central portion 7b of the beam-shaped spacer 7 can be prevented. Although the central portion of the dielectric plate 8 easily sags downward as described above, the central portion of the dielectric plate 8 that sags downward can reliably be prevented from coming in direct contact with the central portion 7b of the beam-shaped spacer 7 by providing the elastic member 25.

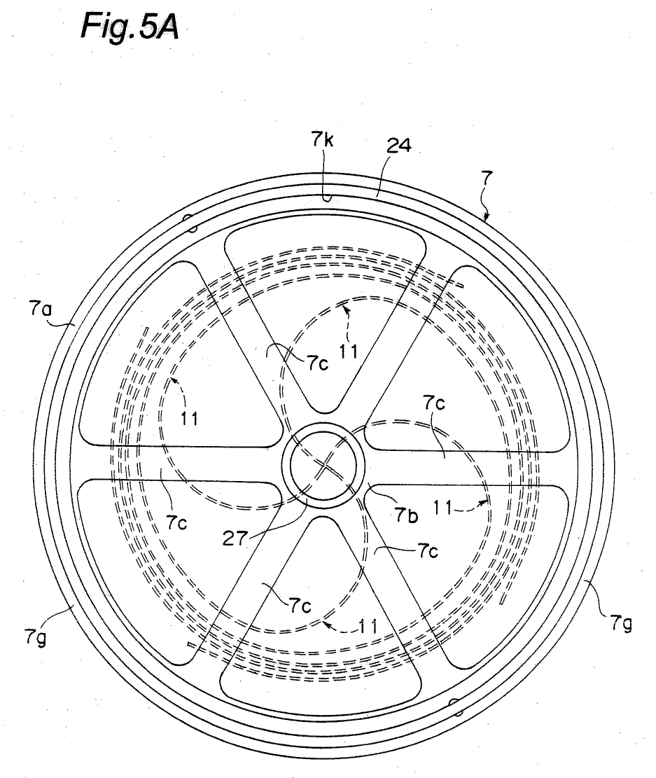

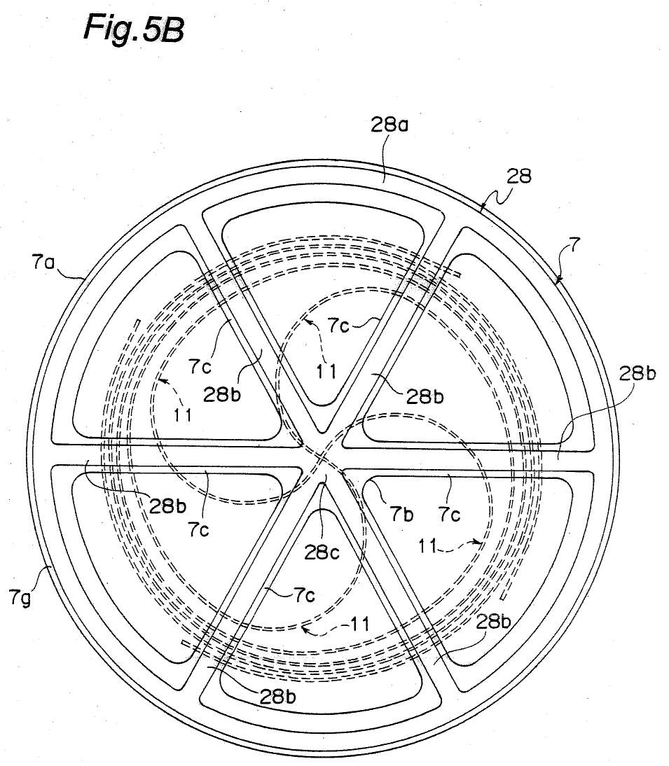

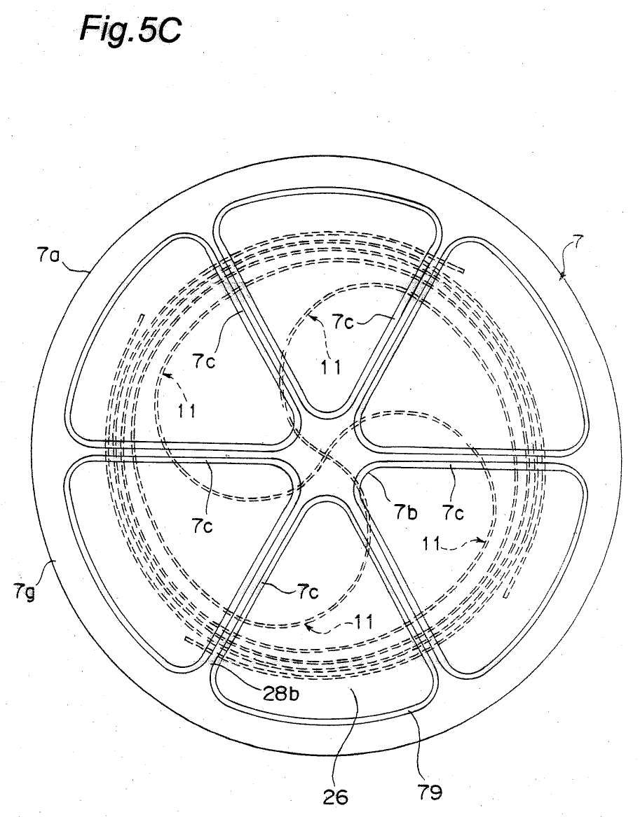

FIGS. 5A through 5C show alternatives of the O-ring or the elastic member interposed between the beam-shaped spacer 7 and the dielectric plate 8. In the example of FIG. 5A, an O-ring 27 of a smaller diameter is placed concentrically with the O-ring 24 of the outer peripheral portion 7a at the central portion 7b of the beam-shaped spacer 7. In FIG. 5B, an elastic member 28 is placed on the entire upper surface 7g of the beam-shaped spacer 7. In detail, the elastic member 28 has an annular portion 28a placed at the outer peripheral portion 7a of the beam-shaped spacer 7, a strip-shaped portion 28b (third elastic member) placed at each of the beam portions 7c, and a portion 28c formed by connecting the strip-shaped portions 28b at the central portion 7b. In FIG. 5C, a groove is provided on the upper surface 7g of the beam-shaped spacer 7 so as to surround the individual window portions 26, and an O-ring 79 is placed in the groove.

As described above, the beam portions 7c of the beam-shaped spacer 7 extend in the direction perpendicular to the portion in which the turn density of the conductors 1 that constitute the ICP coil 9 is dense. Therefore, an electromagnetic influence that the beam-shaped spacer 7 exerts on the electromagnetic fields generated around the conductors 1 of the ICP coil 9 when the high-frequency power is applied from the high-frequency power source 13 can be suppressed. As a result, the loss of the applied high-frequency power can be further reduced. In order to obtain the effect of reducing the loss, the beam portions 7c and the portion in which the turn density of the conductors 1 is dense need not always be accurately perpendicular to each other, and both of them only need to be substantially perpendicular to each other. For example, when the beam portions 7c and the conductors 1 intersect each other at an angle of approximately 90°±10° in plane view, the effect of reducing the loss is obtained. It is preferred that the number of the beam portions 7c of the beam-shaped spacer 7 (six) and the number of the conductors 1 that constitute the ICP coil 9 (six) coincide with each other as shown in FIG. 4B in addition to the arrangement that the conductors 1 are perpendicular to the beam portions 7c in plane view. With this arrangement, the symmetry of the electromagnetic fields generated when the high-frequency power is applied to the ICP coil 9 from the high-frequency power source 13 is improved, and therefore, the loss due to the existence of the beam portions 7c can be further reduced.

As described above, the dielectric plate 8 is made of yttrium oxide. For example, when the Si substrate is etched deeply at high speed, it is necessary to increase the pressure in the chamber 3 in order to increase the radicals. In this case, the sputtering to the dielectric plate is increased as a consequence of an increase in capacitive coupling in the plasma generating mode. Therefore, the wastage of the dielectric plate is significant when the dielectric plate is made of quartz, and it is necessary to replace the dielectric plate in a relatively short time. In contrast to this, by making the dielectric plate 8 of yttrium oxide, the wastage of the dielectric plate can be largely reduced particularly in a high-pressure condition in which the capacitive coupling increases. In concrete, the wastage of the dielectric plate 8 made of yttrium oxide is approximately one hundredth of the wastage of the dielectric plate made of quartz under the high-pressure condition in which the capacitive coupling increases.

As an alternative, the dielectric plate 8 may be made of aluminum nitride (AlN) or quartz. In general, yttrium oxide has a low resistance to thermal impact, and a large temperature gradient in the material causes cracks. In contrast to this, aluminum nitride has a higher resistance to thermal impact than that of yttrium oxide although it falls short of yttrium oxide in terms of wear resistance under the condition that the capacitive coupling becomes dominant in the plasma generating mode. Therefore, when aluminum nitride is adopted as the dielectric plate 8, cracks due to the temperature gradient in the dielectric plate 8 can be effectively prevented. Moreover, quartz has a higher resistance to thermal impact than that of yttrium oxide or aluminum nitride although it is significantly inferior to yttrium oxide and aluminum nitride in terms of wear resistance under the condition that the capacitive coupling becomes dominant in the plasma generating mode. Moreover, the dielectric plate made of quartz exerts a smaller influence than that of yttrium oxide or aluminum oxide on the processing when cracks are generated.

A construction for introducing the process gas into the chamber 3 is described next in detail.

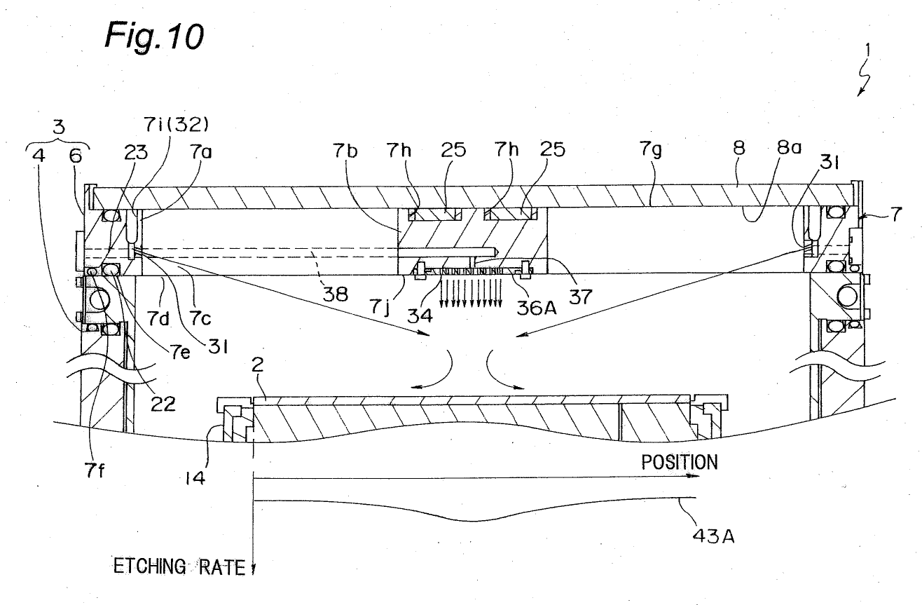

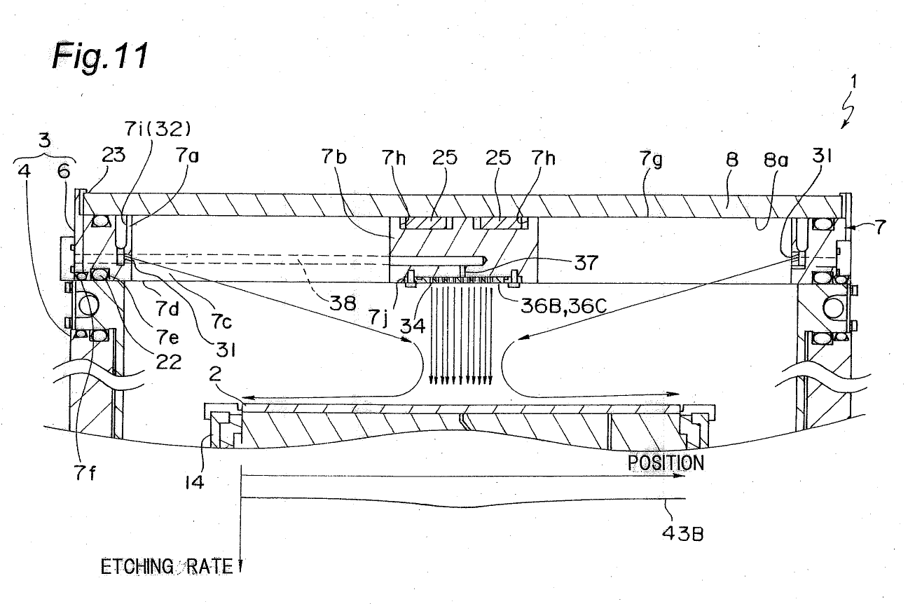

Referring to FIGS. 1, 2 and 6, a plurality of (six in the present embodiment) gas inlet ports (outer peripheral gas inlet ports) 31 are formed at an inner sidewall 7m opposed to the central portion 7b at the outer peripheral portion 7a of the beam-shaped spacer 7. The six gas inlet ports 31 are arranged at equiangular intervals in plane view and opened at respective window portions 26. Moreover, the direction and shape of each individual gas inlet port 31 are set so that the process gas is ejected obliquely downwardly, i.e., toward the vicinity of the center of the surface of the substrate 2 retained by the substrate susceptor 14 through the window portions 26. An annular gas passage groove 7i is formed inwardly of the O-ring 24 at the upper surface 7g of the outer peripheral portion 7a of the beam-shaped spacer 7. The gas passage groove 7i has an upper opening closed with the lower surface 8a of the dielectric plate 8, and an annular gas passage 32 sealed in the gas passage groove 7i is formed. Referring to FIG. 6, each of the gas inlet ports 31 communicates when the annular gas passage 32. Referring to FIGS. 1 and 2, an inlet passage 33 whose one end communicates with the annular gas passage 32 and the other end is connected to the process gas supply source 19 is provided. Therefore, the process gas supplied from the process gas supply source 19 is ejected from the gas inlet ports 31 into the chamber 3 through the inlet passage 33 and the annular gas passage 32. As described above, the gas inlet ports 31 are formed at the outer peripheral portion 7a of the beam-shaped spacer 7 and obliquely downwardly eject the process gas. Therefore, the process gas ejected from the gas inlet ports 31 is directed from the outer peripheral portion toward the central portion of the substrate 2 retained on the substrate susceptor 14 (see FIGS. 10 and 11).

Referring to FIGS. 1, 2 and 7, a receiving recess portion 7j is formed at the central portion 7b of the beam-shaped spacer 7, and a replaceable inlet port plate (central inlet port member) 36A, at which a gas inlet port (central gas inlet port) 34 is formed, is received in the receiving recess portion 7j. An inlet gas passage 37 whose one end communicates with each individual second gas inlet port 34 via a gas distribution chamber 41 is formed at the central portion 7b of the beam-shaped spacer 7. As most clearly shown in FIG. 2, the gas passage 38 extends from the sidewall outer peripheral surface of the outer peripheral portion 7a of the beam-shaped spacer 7 through the inside of one (beam portion 7c that extends in the direction of “9 o'clock” in FIG. 2) of the six beam portions 7c and reaches the central portion 7b. The gas passage 38 whose end portion on the outer peripheral portion 7a side is closed penetrates the gas passage groove 71 in the portion indicated by the reference sign “A” in FIG. 2, and the process gas in the annular gas passage 32 flows from the portion into the gas passage 38. The other end of the inlet gas passage 37 communicates with the gas passage 38.

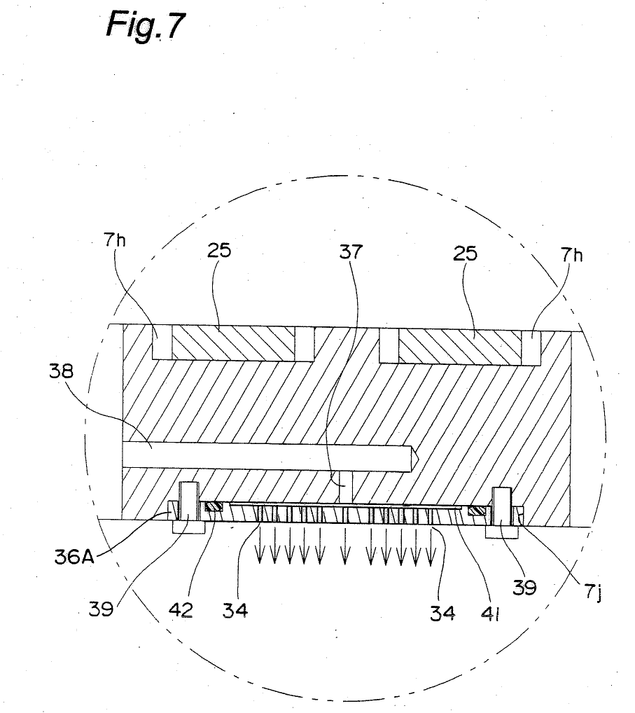

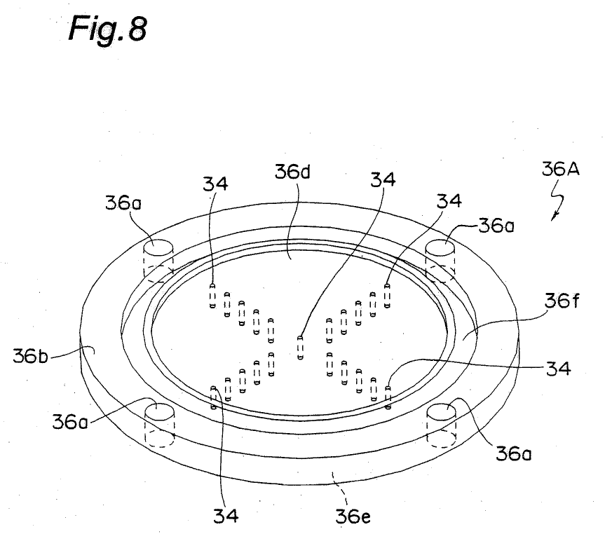

Referring to FIGS. 7 and 8, the inlet port plate 36A has through holes (four holes in the present embodiment) 36a that penetrate through the thickness direction in the vicinity of the outer peripheral edge. By screwing a screw 39 penetrating the through hole 36a into a threaded hole formed at the bottom wall of the receiving recess portion 7j, the inlet port plate 36A is fixed to the inside of the receiving recess portion 7j. Moreover, a recess portion 36d is formed in a central portion of an upper surface 36b of the inlet port plate 36A. The gas distribution chamber 41 that communicates with the inlet gas passage 37 is formed of the recess portion 36d and the bottom wall of the receiving recess portion 7j. The gas inlet ports 34 extend in a perpendicular direction from the bottom wall of the recess portion 36d and penetrate to a lower surface 36e of the inlet port plate 36A. In the inlet port plate 36A shown in FIG. 8, one gas inlet port 34 is placed at the center of the recess portion 36d, and four arrays, each of which is constructed of five gas inlet ports 34, are radially arranged at equiangular intervals from the gas inlet port 34 located at the center. Moreover, in the inlet port plate 36A shown in FIG. 8, bore diameters of all the gas inlet ports 34 are set identical. Further, an annular groove 36f that surrounds the recess portion 36d is formed on the upper surface 36b of the inlet port plate 36A, and sealability of the inside of the gas distribution chamber 41 is secured by an O-ring 42 received in the annular groove 36f. The process gas supplied from the process gas supply source 19 is ejected from the gas inlet ports 34 of the inlet port plate 36A into the chamber 3 by way of the inlet passage 33, annular gas passage 32, gas passage 38, inlet gas passage 37 and gas distribution chamber 41. The gas inlet ports 34 are provided at the inlet port plate 36A attached to the central portion 7b of the beam-shaped spacer 7 and downwardly eject the process gas. Therefore, the process gas ejected from the second gas inlet ports 34 is directed toward the central portion of the substrate 2 retained on the substrate susceptor 14 (see FIGS. 10 and 11).

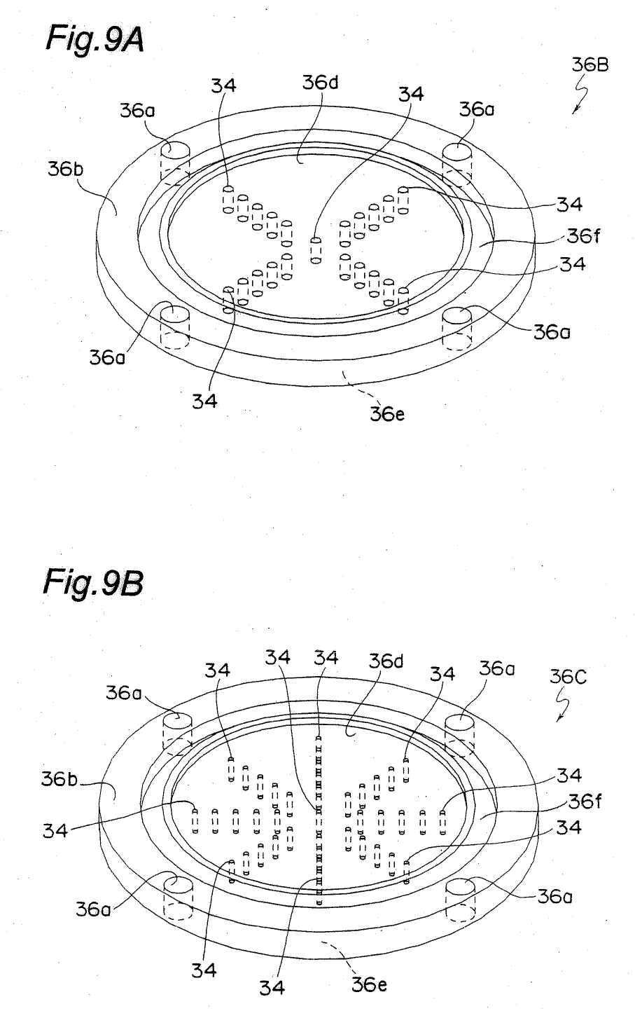

FIGS. 9A and 9B show examples of inlet port plates 36B and 36C for replacement. In the case of the inlet port plate 36B of FIG. 9A, the number and arrangement of the gas inlet ports 34 are identical to those of the inlet port plate 36A of FIG. 8, whereas the bore diameter of the gas inlet ports 34 is set greater than that of the inlet port plates 36A of FIG. 8. In the case of the inlet port plate 36C of FIG. 9B, the bore diameter of the gas inlet ports 34 is identical to that of the inlet port plate 36A of FIG. 8, whereas the number and arrangement of the gas inlet ports 34 differ from those of the inlet port plates 36A of FIG. 8. In detail, one gas inlet port 34 is placed at the center of the recess portion 36d, and eight arrays, each of which is constructed of five gas inlet ports 34, are radially arranged from the gas inlet port 34 located at the center. The shape, dimension, arrangement and number of the gas inlet ports 34 provided at the inlet port plate are not limited to those shown in FIGS. 8 through 9B but allowed to be appropriately set.

With the replacement of the inlet port plates 36A through 36C, the flow rate of the process gas ejected from the gas inlet ports 34, i.e., the process gas directed from just above the central portion of the substrate 2 downwardly perpendicularly to the central portion of the substrate 2 can be simply adjusted. Therefore, with the replacement of the inlet port plates 36A through 36C in accordance with the processing conditions, the dimensions of the substrate 2 and so on, it is possible to adjust the ratio between the flow rates of the process gas ejected from the gas inlet ports 31 and the gas inlet ports 34 and thereby simply uniformize the gas flow rates in the entire region on the substrate 2 including the peripheries of the substrate 2. For example, as shown in FIG. 10, if the inlet port plate 36A of FIG. 8 is attached to the central portion 7b of the beam-shaped spacer 7 as shown in FIG. 10, then the flow rate of the process gas ejected from the gas inlet port 34 located at the center becomes insufficient with respect to the flow rate of the process gas ejected from the peripheral gas inlet ports 31, and this sometimes causes a case where the process gas ejected from the gas inlet ports 31 tend to stay at the central portion of the substrate 2. In this case, the etching rate at the central portion of the substrate 2 becomes higher than the etching rate at the peripheral portions as indicated by the reference numeral 43A in FIG. 10, failing in achieving a uniform etching process. In contrast to this, as shown in FIG. 11, if the inlet port plate 36B (in which the bore diameter of the gas inlet port 34 is larger than that of the inlet port plate 36A of FIG. 8) of FIG. 9A or the inlet port plate 36C (in which the number of the gas inlet ports 34 is greater than that of the inlet port plate 36A of FIG. 8) of FIG. 9B is attached to the central portion 7b of the beam-shaped spacer 7, then the flow rate of the process gas ejected from the second gas inlet port 34 is increased. In this case, the process gas ejected from the peripheral gas inlet ports 31 joins the flow of the process gas ejected from the gas inlet port 34 located at the center and flows along the surface of substrate 2 toward the outer peripheral portion without staying in the central portion of the substrate 2. Therefore, variation in the etching rate between the central portion and the peripheral portion of the substrate 2 is remarkably reduced as indicated by the reference numeral 43B in FIG. 11, resulting in a uniform etching process. As described in detail later, the ratio between the flow rates of the process gas ejected from the gas inlet ports 31 and the gas inlet port 34 may be changed by changing the shape, dimension, arrangement, number and so on of the gas inlet ports 31 provided at the outer peripheral portion 7a of the beam-shaped spacer 7 and thereby uniformize the etching process.

### Second Embodiment

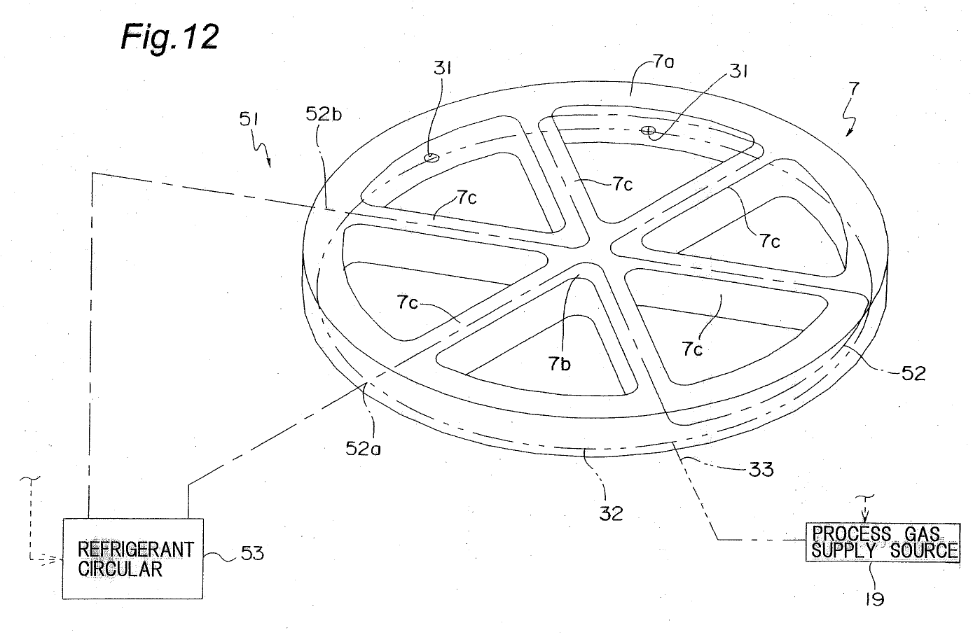

FIG. 12 shows the second embodiment of the present invention. Although FIG. 12 shows only the beam-shaped spacer 7, the overall structure of the dry etching apparatus 1 of the second embodiment is identical to that of the first embodiment (see FIG. 1).

An annular gas passage 32 and gas inlet ports 31 are formed at the outer peripheral portion 7a of the beam-shaped spacer 7, and the annular gas passage 32 is connected to the process gas supply source 19 via the inlet passage 33. Although not shown in FIG. 12, an inlet port plate 36A (see FIGS. 1 and 8) having a gas inlet port 34 is attached to the central portion 7b of the beam-shaped spacer 7. These arrangements are similar to those of the first embodiment.

In the present embodiment, the beam-shaped spacer 7 and a cooling mechanism 51 that cools the dielectric plate 8 are provided. The cooling mechanism 51 has a refrigerant passage 52 provided at the outer peripheral portion 7a and the beam portions 7c of the beam-shaped spacer 7, and a refrigerant circulator 53 that supplies a temperature-controlled refrigerant. An inlet 52a and an outlet 52b of the refrigerant passage 52 are connected to the refrigerant circulator 53, and the refrigerant supplied from the refrigerant circulator 53 circulates in the refrigerant passage 52, thereby cooling the beam-shaped spacer 7. Moreover, since the dielectric plate 8 is placed on the beam-shaped spacer 7, the dielectric plate 8 is also cooled by the cooling of the beam-shaped spacer 7. By cooling the beam-shaped spacer 7 and the dielectric plate 8 by the cooling mechanism 51, changes in the process characteristics due to temperature rises of the beam-shaped spacer 7 and the dielectric plate 8, adhesion of deposits and exfoliation of deposits can reliably be prevented even if the state in which the plasma is generated by applying the high-frequency power into the ICP coil 9 (see FIG. 1) is continued for a long time.

The other constructions and effects of the second embodiment are similar to those of the first embodiment.

### Third Embodiment

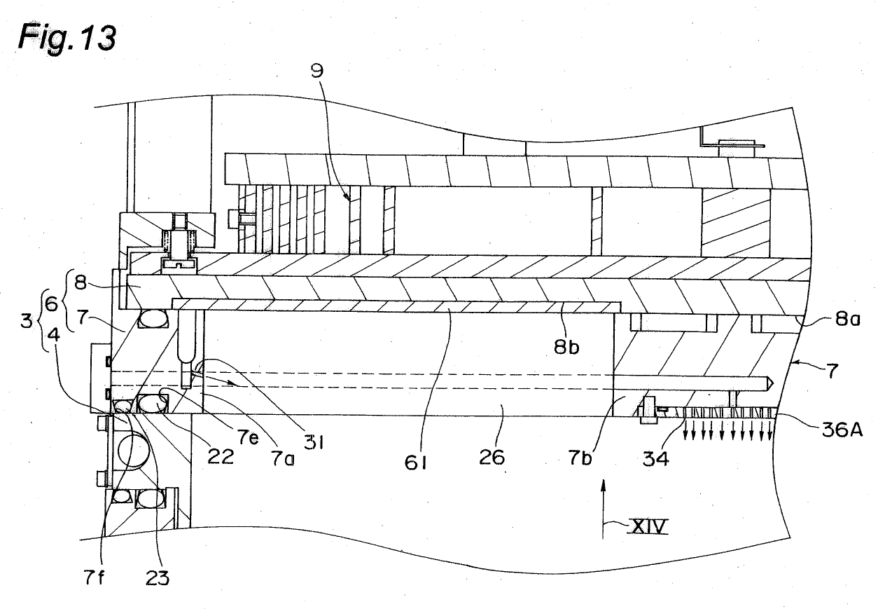

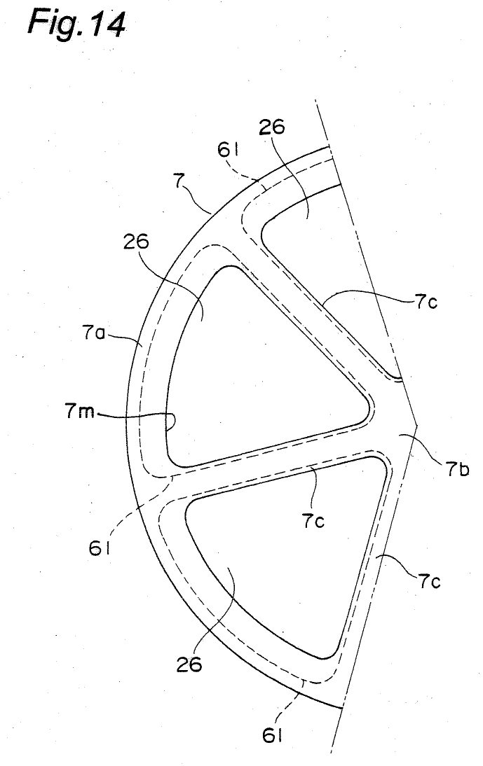

FIGS. 13 and 14 show the third embodiment of the present invention. The overall structure of the dry etching apparatus 1 of the third embodiment is identical to that of the first embodiment (see FIG. 1).

In the present embodiment, the dielectric plate 8 is made of quartz. Moreover, a ultrathin cover 61 made of yttrium oxide is attached to a portion that belongs to the lower surface 8a sides of the dielectric plate 8 and is exposed to the inside of the processing chamber of the chamber 3 via the window portions 26 of the beam-shaped spacer 7. Since six window portions 26 are provided at the beam-shaped spacer 7 (see also FIG. 2), six pieces of covers 61 are attached as the cover 61 in correspondence with them. Recess portions 8b are formed in positions (six places) corresponding to the window portions 26 at the lower surface 8a of the dielectric plate 8, and the covers 61 are received in the respective recess portions 8b. The lower surface of each individual cover 61 constitutes same plain with the lower surface 8a of the dielectric 8. Moreover, the vicinity of the outer peripheral edge of each individual cover 61 is interposed between the beam-shaped spacer 7 and the dielectric plate 8.

By arranging the covers 61 made of yttrium oxide at the window portions 26, the wastage of the dielectric plate 8 made of quartz can be largely reduced even in a high-pressure condition in which the capacitive coupling particularly increases. Moreover, since the covers 61 made of yttrium oxide are provided not on the entire lower surface 8a side of the dielectric plate 8 but in only the portions exposed from the window portions 26, and therefore, the area of each individual cover 61 can be set small. Since the yttrium oxide material has low rigidity, the yttrium oxide material of a large area and a thin thickness has low strength. However, each individual cover 61, which has a piece-like shape of a small area, is able to be reduced in thickness while securing a sufficient strength. In concrete, the thickness of the cover 61 can be set to approximately 1 mm to 5 mm, or more precisely to approximately 2 mm. Moreover, since a uniform temperature is maintained during the plasma processing because the cover 61 has a small area and a thin thickness, the generation of cracks due to the temperature gradient can be prevented. Further, in comparison with the case where the dielectric plate 8 itself is made of yttrium oxide and the case where the entire lower surface 8a of the dielectric plate 8 is covered with the yttrium oxide material, the amount of use and cost of yttrium oxide be largely reduced because the covers 61 made of yttrium oxide are provided only in the portions exposed from the window portions 26 of the dielectric plate 8, i.e., only the portions that need protection because of exposition to plasma.

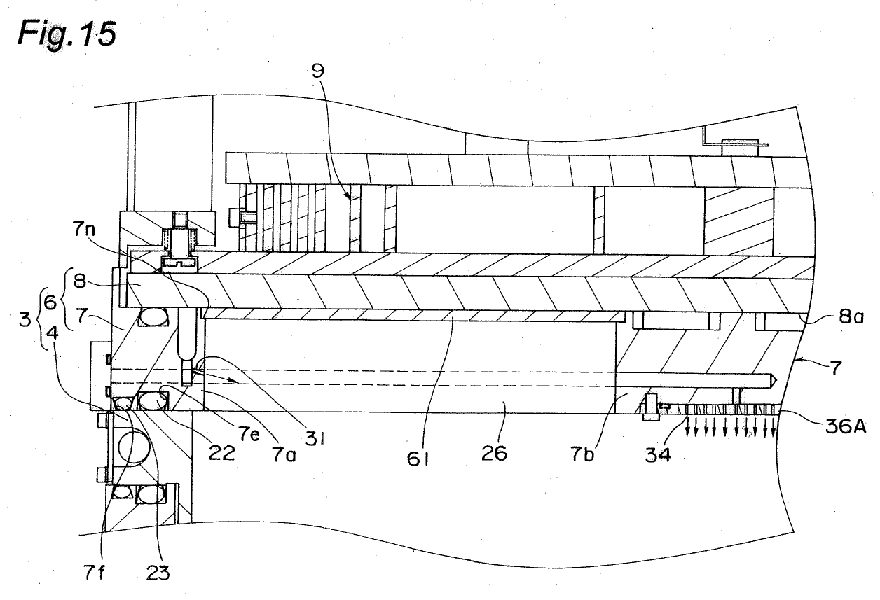

Although the lower surface of the cover 61 constitutes same surface with the lower surface 8a of the dielectric plate 8, the attaching or placing positions of the covers 61 to the dielectric plate 8 are not particularly limited so long as the wastage of the dielectric plate 8 due to the exposure to plasma can be reduced. For example, as shown in FIG. 15, the lower surface side of the outer peripheral edge of the cover 61 may be placed in a recess portion 7n provided on the beam-shaped spacer 7 side and thereby make the upper surface of the cover 61 flush with the lower surface 8a of the dielectric plate 8. Moreover, the cover 61 may be attached to the dielectric plate 8 so that neither the lower surface nor the upper surface of the cover 61 becomes flush with the lower surface 8a of the dielectric plate 8. Further, the cover 61 may be placed so that a gap exists between it and the lower surfaces 8a of the dielectric plate 8.

The other constructions and effects of the third embodiment are similar to those of the first embodiment. The cooling mechanism 51 (see FIG. 12) of the second embodiment may be applied to the third embodiment. Since the temperature of the covers 61 can be maintained almost constant by providing the cooling mechanism 51, cracks of the covers 61 due to the temperature gradient can more reliably be prevented.

The covers 61 (see FIGS. 13 through 15), which are made of yttrium oxide in the third embodiment, may be made of single crystal sapphire. Since the single crystal sapphire is more resistive to a thermal impact than yttrium oxide, cracks of the covers 61 can be reliably prevented even in an environment to which a greater temperature gradient is given. The case where the cover is made of single crystal sapphire is similar to the third embodiment in that the attaching or placing positions of the covers 61 to the dielectric plate 8 are not particularly limited. The covers 61 may be made of alumina (Al₂O₃) including aluminum oxide in place of the single crystal sapphire and yttrium oxide.

### Fourth Embodiment

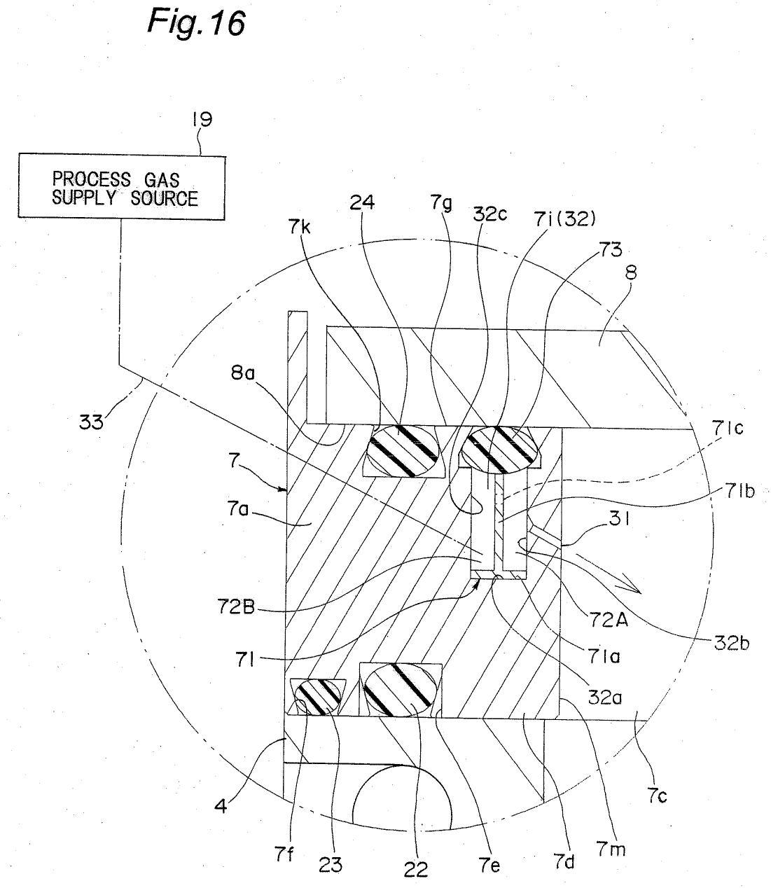

The dry etching apparatus 1 of the fourth embodiment of the present invention shown in FIG. 16 has a partition ring 71 in the annular gas passage 32 formed at the outer peripheral portion 7a of the beam-shaped spacer 7. As described above, the annular gas passage 32 is formed of the annular gas passage groove 7i formed inwardly of the O-ring 24 at the upper surface 7g of the outer peripheral portion 7a. The annular gas passage 32 has a bottom wall 32a, and an inner peripheral wall 32b and an outer peripheral wall 32c, which extend from the bottom wall 32a perpendicularly upwardly. The basal end side of the gas inlet port 31 is opened at the inner peripheral wall 32b. Moreover, an inlet passage 33 connected to the process gas supply source 19 is opened at the outer peripheral wall 32c. Further, a receiving portion 32d of which the passage width is expanded is formed on the upper end side of the annular gas passage 32. An O-ring 73 is received in the receiving portion 32d. The O-ring 73 is put in tight contact with the lower surface 8a of the dielectric plate 8, by which the annular gas passage 32 is internally sealed.

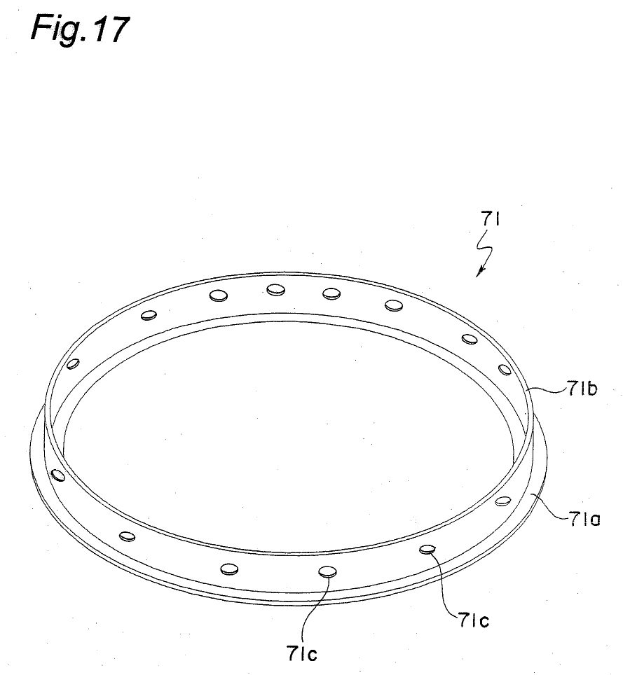

Referring also to FIG. 17, the partition ring 71 has a flat annular basal portion 71a, and a partition wall 71b that extends upwardly from the basal portion 71a. The diameter and width of the basal portion 71a almost coincide with those of the annular gas passage 32a. The basal portion 71a is received in the annular gas passage 32 with its lower surface placed on the bottom wall 32a and its inner peripheral edge and the outer peripheral edge put in contact with the inner peripheral wall 32b and the outer peripheral wall 32c, respectively. The partition wall 71b projects perpendicularly upwardly almost from the center in the widthwise direction of the basal portion 71a. The partition wall 71b has its lower end connected to the basal portion 71a and its upper end put in tight contact with the lower side of the O-ring.

The partition wall 71b of the partition ring 71 partitions the inside of the annular gas passage 32 into a discharge space 72A located on the inner peripheral wall 32a side (gas inlet port 31 side) and a supply space 72B located on the outer peripheral wall 32c side (process gas supply source 19 side). In detail, the annular discharge space 72A is formed inwardly of the partition wall 71b, and the annular supply space 72B is formed outwardly of the partition wall 71b. A plurality of communication holes 71c that penetrate through the thickness direction are provided at intervals at the partition wall 71b. The discharge space 72A and the supply space 72B communicate with each other via only these communication holes 71c.

The process gas supplied from the process gas supply source 19 to the annular gas passage 32 via the inlet passage 33 first enters the supply space 72B. The process gas enters the discharge space 72 through the plurality of communication holes 71c while annularly diffusing in the supply space 72B. The process gas is ejected from the gas inlet ports 31 into the chamber 3 while further diffusing in the discharge space 72B. Since the process gas is preparatorily diffused in the annular supply space 72B and thereafter supplied to the discharge space 72A located on the gas exhaust port 31 side, the flow rate of the gas ejected from one or a plurality of specified gas inlet ports 31 does not become greater than that of the remaining gas inlet ports 31. In other words, the flow rate of the process gas ejected from the plurality of gas inlet ports 31 is uniformized by the rectifying action of the partition wall 71b of the partition ring 71.

The other constructions and effects of the fourth embodiment are similar to those of the first embodiment.

### Fifth Embodiment

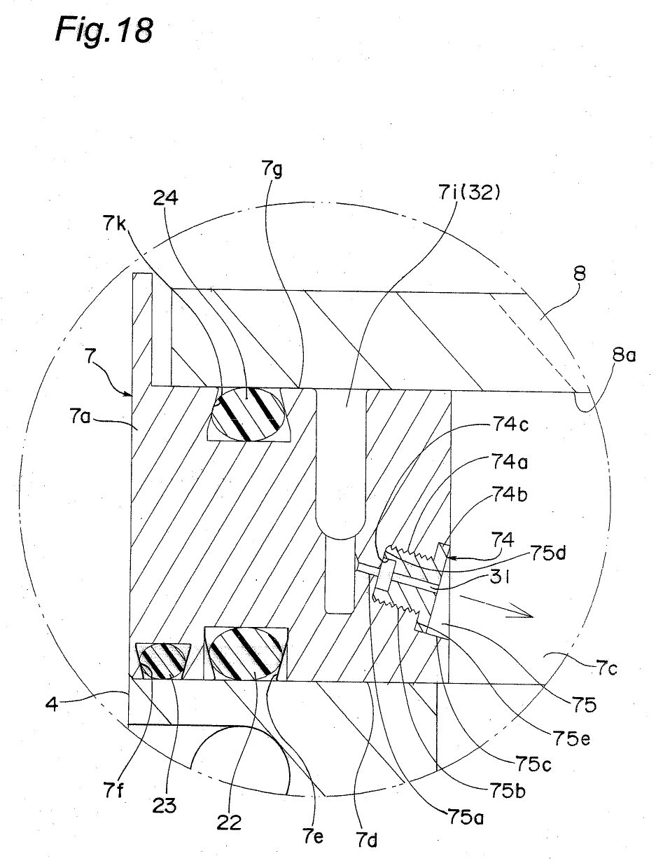

The dry etching apparatus 1 of the fifth embodiment of the present invention shown in FIG. 18 has a plurality of inlet port chips (outer peripheral side inlet port members) 74 replaceably attached to the outer peripheral portion 7a of the beam-shaped spacer 7, and one gas inlet port 31 is provided at each individual inlet port chip 74.

A plurality of mounting holes 75, which are oriented obliquely downwardly from the inner peripheral wall 32b of the annular gas passage 32 to the inner sidewall 7m and have a circular cross-section shape, are provided at the outer peripheral portion 7a of the beam-shaped spacer 7. The inlet port chip 74 is detachably attached to each individual mounting hole 75. Each of the mounting holes 75 has an inlet portion 75a that communicates with the annular gas passage 32, an internal thread portion 75b and an outlet portion 75c opened to the inside of the chamber 3, which are arranged in order from the annular gas passage 32 side. The internal thread portion 75b has a diameter larger than that of the inlet portion 75a, and a seat portion 75d is formed of a stepped portion at a juncture between the internal thread portion 75b and the inlet portion 75a. Moreover, the outlet portion 75c has a diameter larger than that of the internal thread portion 75b, and a seat portion 75e is formed of a stepped portion at a juncture between the outlet portion 75c and the internal thread portion 75b.

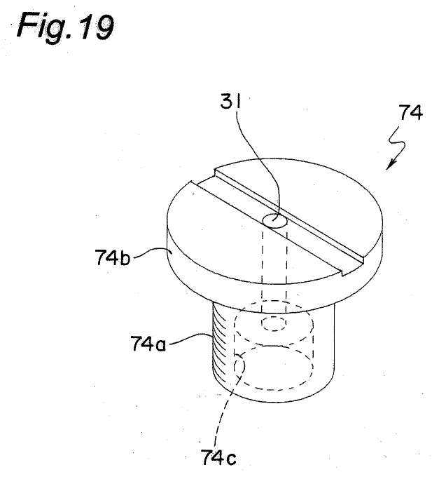

Referring also to FIG. 19, the inlet port chip 74 has an external thread portion 74a and a head portion 74b that is integrally provided at the tip end of the external thread portion 74a. The head portion 74b has a diameter larger than that of the external thread portion 74a. A recess portion 74c is formed at the basal end surface of the external thread portion 74a. The gas inlet port 31 is provided so as to penetrate from the bottom wall of the recess portion 74c to the extreme end surface of the head portion 74b. The gas inlet port 31 extends along the central axis of the inlet port chip 74. The external thread portion 74a of the inlet port chip 74 is screwed into the internal thread portion 75b of the mounting hole 75, by which the inlet port chip 74 is fixed to the outer peripheral portion 7a of the beam-shaped spacer 7. The head portion 74b of the inlet port chip 74 is received in the outlet portion 75c of the mounting hole 75. Moreover, the basal end surface of the external thread portion 74a is placed on the seat portion 75d, and the basal end surface of the head portion 74b is placed on the seat portion 75e.

A path formed of the inlet portion 75a of the mounting hole 75, the recess portion 74c of the inlet port chip 74, and the gas inlet port 31 extends from the annular gas passage 32 to the inside of the chamber 3. The process gas is ejected from the gas inlet port 31 into the chamber 3 through the path.

If a plurality of kinds of inlet port chips 74 of different bore diameters and directions of the gas inlet port 31 are prepared, the bore diameter and direction of the gas inlet port 31 can be changed by replacing the inlet port chip 74. If the supply pressure of the process gas supply source 19 is identical, the flow rate of the process gas to be introduced becomes slower as the bore diameter of the gas inlet port 31 is increased, and the flow rate becomes faster as the bore diameter is reduced. Therefore, by replacement of an inlet port chip 74 that has a gas inlet port 31 varied depending on the processing conditions and the conditions of the dimensions of the substrate 2 and so on, the gas flow rate on the substrate 2 can be uniformized.

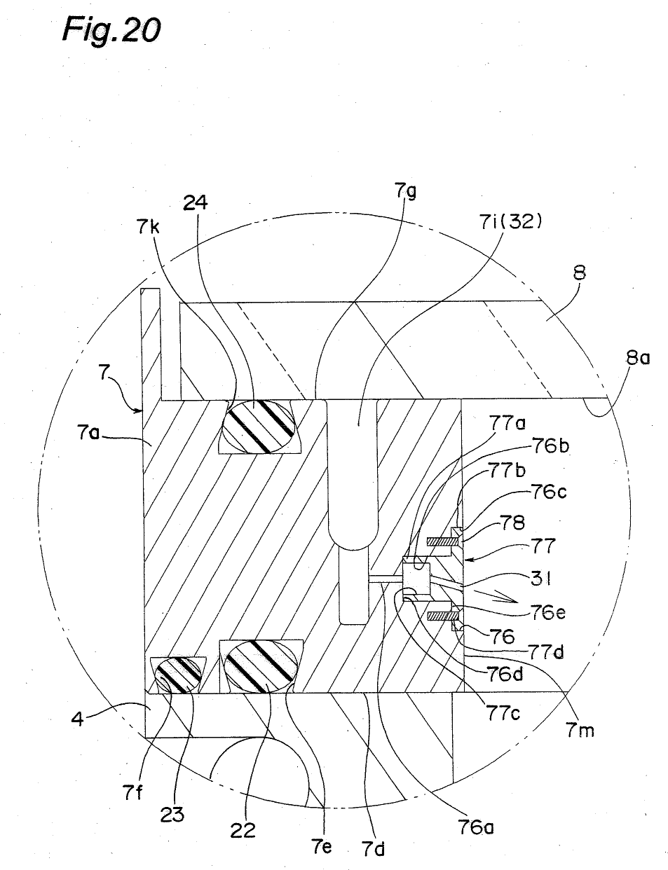

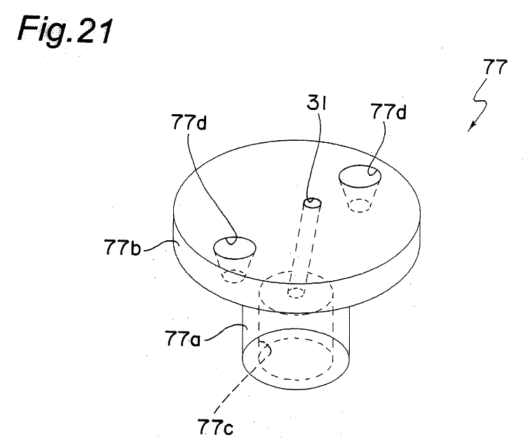

FIGS. 20 and 21 show an alternative of the inlet port chip. According to the present alternative, a plurality of mounting holes 76, which extend horizontally from the inner peripheral wall 32b of the annular gas passage 32 to the inner sidewall 7m and have a circular cross-section shape, are provided at the outer peripheral portion 77b of the beam-shaped spacer 77. Each of the mounting holes 76 has an inlet portion 76a that communicates with the annular gas passage 32, a middle portion 76b of a diameter larger than that of the inlet portion 76a, and an outlet portion 76c of a diameter larger than that of the middle portion 76b in this order from the annular gas passage 32 side. Seat portions 76d and 76e are formed at a juncture between the inlet portion 76a and the middle portion 76b and a juncture between the middle portion 76b and the outlet portion 76c, respectively.

The inlet port chip 77 has a shaft portion 77a, and a head portion 77b provided at the tip end of the shaft portion 77a. The head portion 77b has a diameter larger than that of the shaft portion 77a. A recess portion 77c is formed on the basal end surface of the shaft portion 77b. A gas inlet port 31 is formed so as to penetrate from the bottom wall of the recess portion 77c to the extreme end surface of the head portion 77b. Unlike the inlet port chip 74 of FIG. 19, the gas inlet port 31 is formed inclined with respect to the central axis of the inlet port chip 77. Two through holes 77d are provided at the head portion 77b of the inlet port chip 77. The inlet port chip 77 is inserted into the mounting hole 76 with the shaft portion 77a received in the middle portion 76b and the head portion 77a received in the outlet portion 76c. Moreover, the basal end lower surface of the shaft portion 77a is placed on the seat portion 76d, and the basal end surface of the head portion 77b is placed on the seat portion 76e.

By screwing two screws 78 that penetrate the through holes 77d of the head portion 77a into the threaded holes formed at the inner sidewall 7m of the outer peripheral portion 7a of the beam-shaped spacer 7, the inlet port chip 77 is fixed to the outer peripheral portion 7a of the beam-shaped spacer 7. Moreover, these screws 78 fix the rotational angle position of the inlet port chip 77 itself around the center line, i.e., the orientation of the gas inlet port 31. A path constructed of the inlet portion 76a of the mounting hole 76, the recess portion 77c of the inlet port chip 77, and the gas inlet port 31 is formed from the annular gas passage 32 to the inside of the chamber 3. The process gas is ejected from the gas inlet port 31 into the chamber 3 through the path. If a plurality of kinds of inlet port chips 77 of different bore diameters and directions of the gas inlet port 31 are prepared, it is possible to simply adjust the direction and flow rate of the process gas ejected from the gas inlet port 31 according to the processing conditions, the dimensions of the substrate 2 and so on by replacing the inlet port chip 77, and the gas flow rate on the substrate 2 can be uniformized.

The other constructions and effects of the fifth embodiment are similar to those of the first embodiment.

### Sixth Embodiment

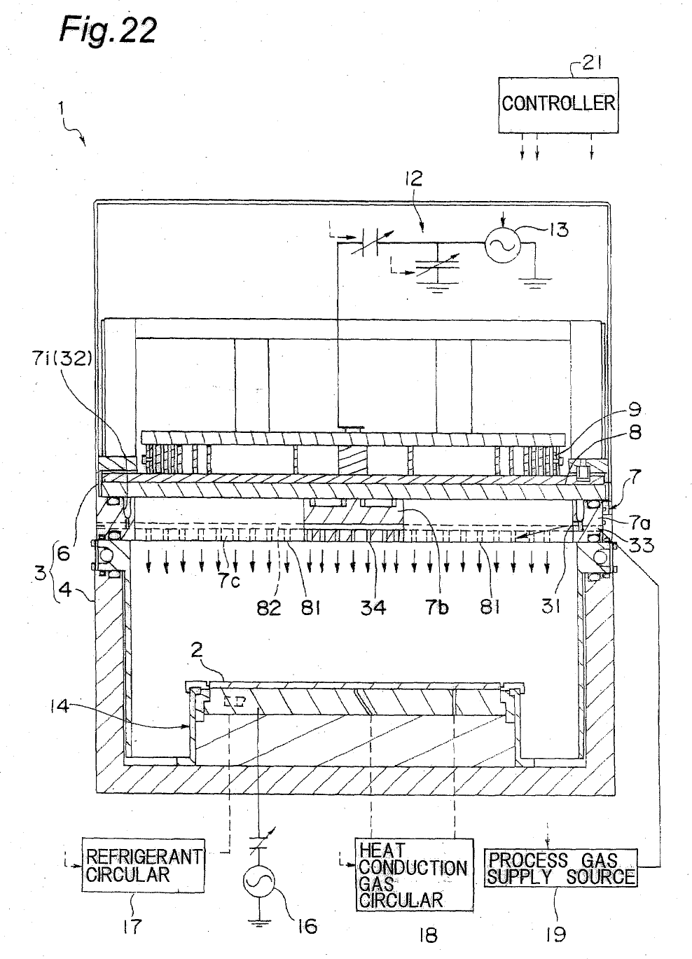

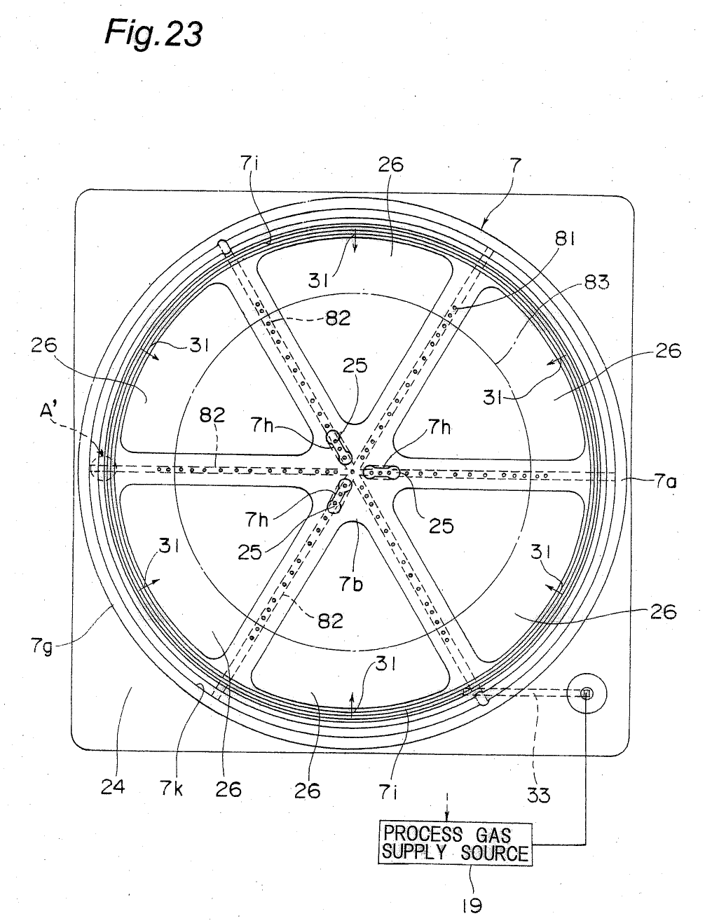

The dry etching apparatus 1 of the sixth embodiment of the present invention shown in FIGS. 22 and 23 has not only gas inlet ports 31 and 34 at the outer peripheral portion 7a and the central portion 7b of the beam-shaped spacer 7 but also a gas inlet port (beam portion gas inlet port) 81 at the beam portion 7c of the beam-shaped spacer 7.

As most clearly shown in FIG. 23, three gas passages 82, which linearly extend from the end portion on the outer peripheral side of one beam portion 7c through the central portion 7b to the end portion on the outer peripheral side of the opposed beam portion 7c are formed at the beam-shaped spacer 7. Among these gas passages 82, the gas passage 82 that extends in the direction of “9 o'clock” in FIG. 23 penetrates the gas passage groove 7i (annular gas passage 32) at the portion indicated by the reference sign “A′” in FIG. 23. Moreover, the three gas passages 82 communicate with one another mutually intersecting at the central portion 7b of the beam-shaped spacer 7.

A plurality of gas inlet ports 81 that are oriented perpendicularly downward are provided on the lower surface side of each individual beam 7c. Moreover, a plurality of gas inlet ports 34 that are oriented perpendicularly downward are provided on the lower surface side of the beam-shaped spacer 7. These gas inlet ports 34 and 81 have a basal end (upper end) side communicating with the gas passage 82 and an extreme end (lower end) side opened in the chamber 3.

The process gas supplied from the process gas supply source 19 is ejected into the chamber 3 from the gas inlet port 31 of the outer peripheral portion 7a of the beam-shaped spacer 7 through the inlet passage 33 and the annular gas passage 32. Moreover, the process gas enters the gas passage 82 from the annular gas passage 32 and is ejected into the chamber 3 also from the gas inlet port 81 of the beam portions 7b and the gas inlet port 34 of the central portion 7b of the beam-shaped spacer 7. Since the process gas is ejected from all of the outer peripheral portion 7a, the central portion 7b and the beam portions 7c of the beam-shaped spacer 7 in the dry etching apparatus 1 of the present embodiment, the gas flow rate can be uniformized more easily in the entire region on the substrate 2 including the periphery of the substrate 2.

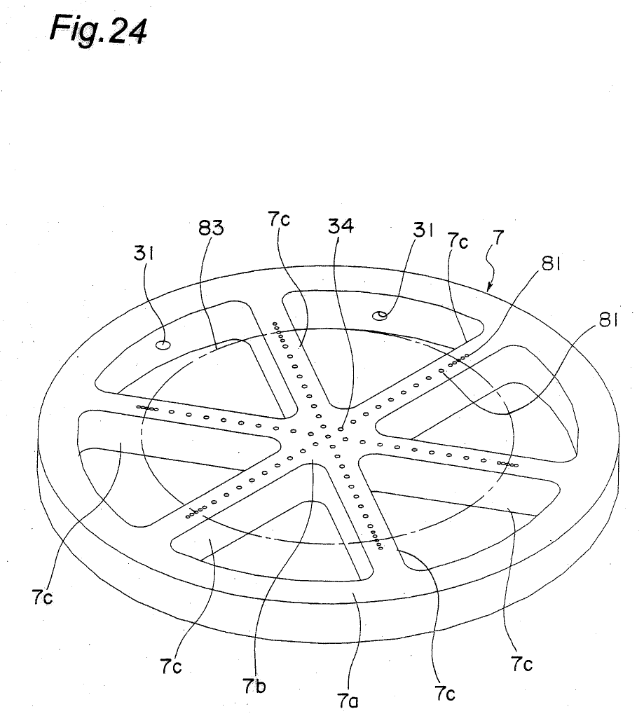

When the gas is ejected from the gas inlet ports placed uniformly along the beam portion 7c, the number of gas inlet ports per unit area above the substrate 2 is smaller at the periphery of the substrate 2 than at the center of the substrate 2. Therefore, the periphery of the substrate 2 tends to have insufficient gas flow rate of the process gas in comparison with the other regions on the substrate 2. In contrast to this, according to the present embodiment, the number of gas inlet ports 81 per unit area provided at the beam portion 7b is set greater than in the other regions in the vicinity of the region corresponding to the periphery of the substrate 2 indicated by the one-dot chain line 83 in FIGS. 23 and 24. With this arrangement, the gas flow rate of the process gas needed for the periphery of the substrate 2 is secured.

The other constructions and effects of the sixth embodiment are similar to those of the first embodiment. Moreover, the gas inlet ports 31, 34, and 81 may be provided at replaceable inlet port chips as described in the fifth embodiment.

### Seventh Embodiment

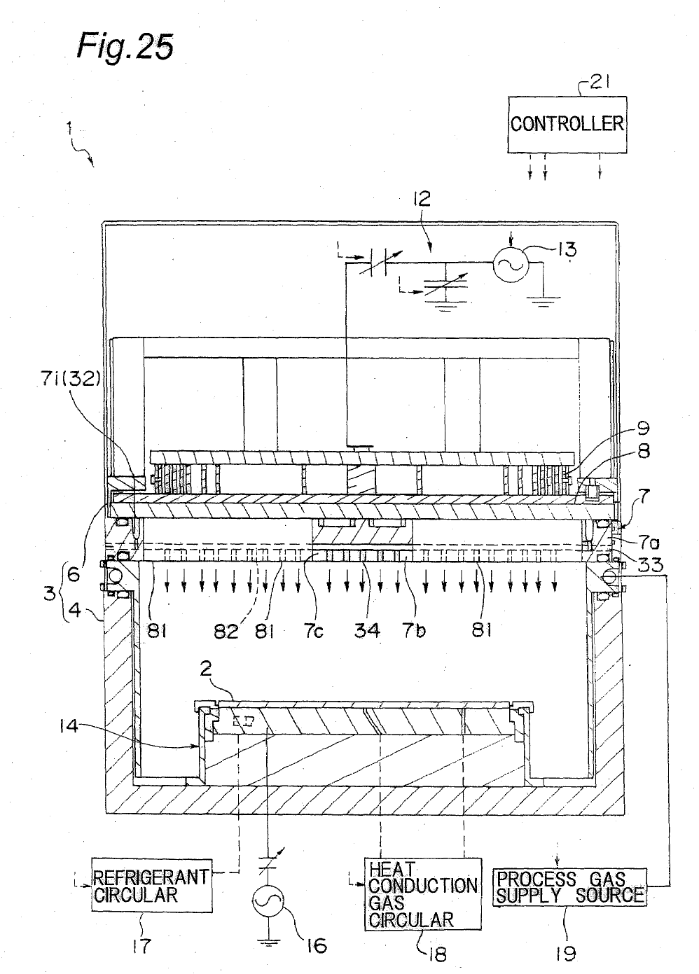

In the seventh embodiment of the present invention shown in FIG. 25, the beam-shaped spacer 7 does not have the gas inlet port 31 of the outer peripheral portion 7a although it has the gas inlet ports 34 and 81 of the central portion 7b and the beam portions 7c (see, for example, FIG. 1).

Depending on the processing conditions and the conditions of the dimensions of the substrate 2 and so on, it is possible to uniformize the gas flow rate on the substrate 2 by ejecting the process gas into the chamber 3 from only the central portion 7b and the beam portions 7c of the beam-shaped spacer 7 as in the present embodiment. The other constructions and effects of the seventh embodiment are similar to those of the first embodiment. Moreover, the gas inlet ports 34 and 81 may be provided at replaceable inlet port chips as described in the fifth embodiment.

### Eighth Embodiment

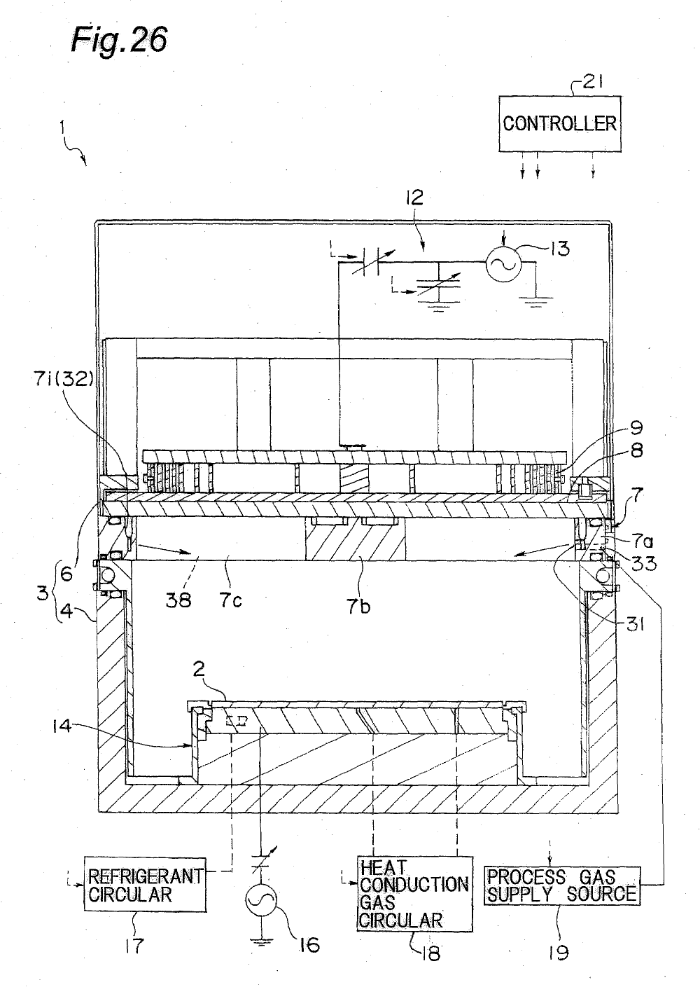

In the eighth embodiment of the present invention shown in FIG. 26, the beam-shaped spacer 7 has neither the gas inlet port 34 (see, for example, FIG. 1) of the central portion 7b nor the gas inlet ports 81 (see, for example, FIG. 22) of the beam portions 7c although it has the gas inlet port 31 of the outer peripheral portion 7a.

Depending on the processing conditions and the conditions of the dimensions of the substrate 2 and so on, it is possible to uniformize the gas flow rate on the substrate 2 by ejecting the process gas into the chamber 3 from only the outer peripheral portion 7a of the beam-shaped spacer 7 as in the present embodiment. The other constructions and effects of the eighth embodiment are similar to those of the first embodiment. Moreover, the gas inlet port 31 may be provided at a replaceable inlet port chip as described in the fifth embodiment.

It is possible to variously modify the first through eighth embodiments. For example, the process gas supply source 19 may be different for each of the three kinds of gas inlet ports provided for the beam-shaped spacer 7, i.e., the gas inlet ports 31 of the outer peripheral portion 7a, the gas inlet port 34 of the central portion 7b and the gas inlet ports 81 of the beam portions 7c.

### Ninth Embodiment

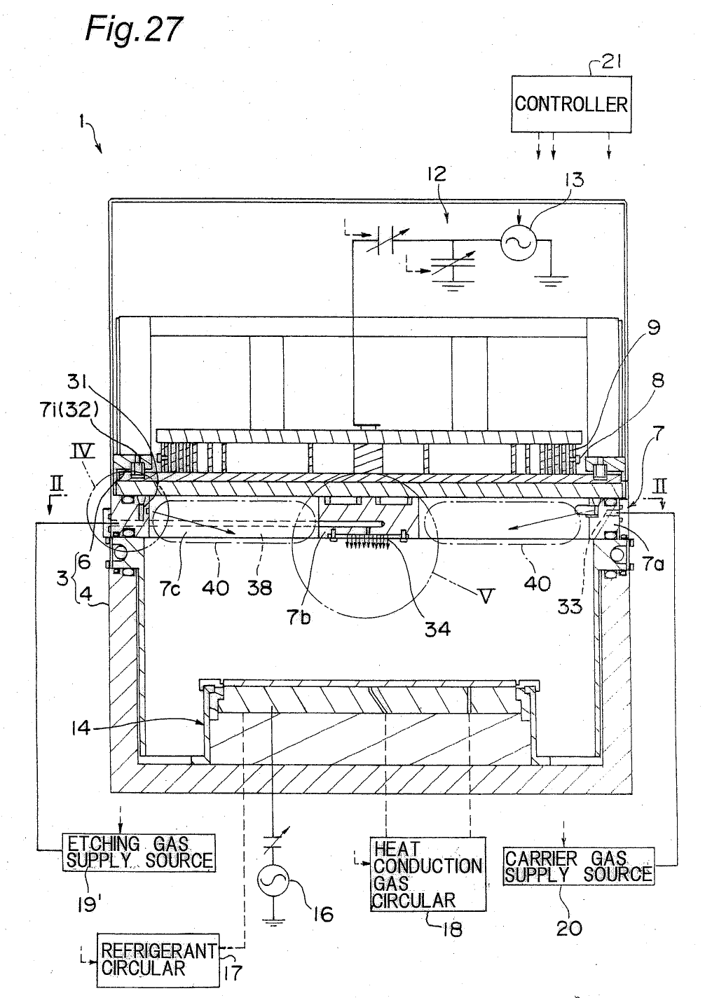

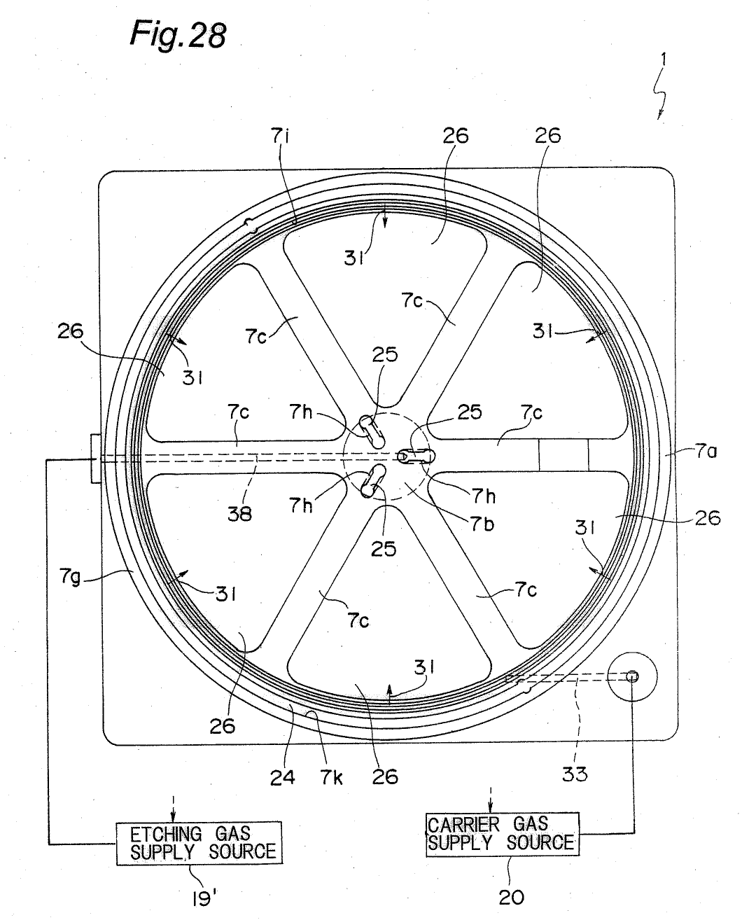

The dry etching apparatus 1 of the ninth embodiment of the present invention shown in FIGS. 27 and 28 has a structure and a function identical to those of the dry etching apparatus 1 of the first embodiment (see FIGS. 1 through 1) except for the arrangements described below. Therefore, same components as those of the first embodiment are denoted by same reference numerals in FIGS. 27 and 28, and detailed description therefor is omitted. Moreover, in the following description, reference is made also to FIGS. 3, 4A and 6 through 8.

As shown in FIG. 27, the gas passage 38 that extends from the outer sidewall of the outer peripheral portion 7a of the beam-shaped spacer 7 through the inside of one beam portion 7c and reaches the central portion 7b does not communicate with the annular gas passage 32 provided at the outer peripheral portion 7a of the beam-shaped spacer 7. Therefore, the gas (etching gas described later) that flows through the gas passage 38 and the gas (carrier gas described later) that flows through the annular gas passage 32 are not mixed.

The annular gas passage 32 is connected to a carrier gas supply source 20 via the inlet passage 33. The carrier gas supplied from the carrier gas supply source 20 is ejected from the gas inlet port (first gas inlet port) 31 into the chamber 3 through the inlet passage 33 and the annular gas passage 32. As described above, the first gas inlet ports 31 are formed at the outer peripheral portion 7a of the beam-shaped spacer 7 and obliquely downwardly eject the gas. Therefore, the carrier gas ejected from the gas inlet ports 31 is directed from the outer peripheral portion toward the central portion of the substrate 2 retained on the substrate susceptor 14 while diffusing in the vacuum.

On the other hand, the gas passage 38 has one end (end portion located on the outer peripheral portion 7a side) connected to an etching gas supply source 19′ and the other end communicating with the inlet gas passage 37. The etching gas supplied from the etching gas supply source 19′ is ejected into the chamber 3 from the gas inlet port (second gas inlet port) 34 of the inlet port plate 36 by way of the gas passage 38, the inlet gas passage 37 and the gas distribution chamber 41. Since the gas inlet port 34 is provided at the inlet port plate 36 attached to the central portion 7b of the beam-shaped spacer 7 and downwardly ejects the etching gas, the etching gas ejected from the gas inlet port 34 is directed toward the central portion of the substrate 2 retained on the substrate susceptor 14 while diffusing in the vacuum.

When a high-frequency power is applied to the ICP coil 9 from the high-frequency power source 13, intense magnetic fields (intense alternating electric fields) are formed at the window portions 26 of the beam-shaped spacer 7 as schematically indicated by the reference numeral 40 in FIG. 27. Since the carrier gas, which is obliquely downwardly ejected from the gas inlet ports 31 formed at the outer peripheral portion 7a of the beam-shaped spacer 7, it passes through the intense magnetic fields 40. As a result, the carrier gas is sufficiently dissociated or ionized. Plasma is generated and maintained in the chamber 3 by the dissociation and ionization of the carrier gas. On the other hand, the etching gas, which is downwardly ejected toward the central portion of the substrate 2 from the second gas inlet port 34 formed at the central portion 7b of the beam-shaped spacer 7, does therefore not pass through the intense magnetic fields 40 formed at the window portions 26. Therefore, the etching gas is neither excessively dissociated nor ionized. Radicals generated by the dissociation in the plasma diffuses to the substrate 2 along the gas flow, whereas ions collide with the substrate 2 by being accelerated by the negative bias voltage that is generated by being applied from the high-frequency power source 16 to the substrate susceptor 14. Then, the surface of the substrate 2 is etched by the actions of the radicals and ions. That is, the excessive dissociation and ionization of the etching gas can be suppressed while the carrier gas is sufficiently dissociated and ionized in the present embodiment. Therefore, the controllabilities of the etching rate, selection ratio, etching shape and so on are remarkably improved, and a satisfactory etching process can be achieved. In other words, it is possible to individually control the ratio between the radicals and ions for each of the etching gas and the carrier gas and thereby achieve a satisfactory etching process.

Moreover, the dry etching apparatus 1 of the present embodiment has a relatively simple structure in that the first and second gas inlet ports 31 and 34 are both provided at the beam-shaped spacer 7 and that neither a gas inlet port nor a gas passage needs to be provided at the dielectric plate 8.

### Tenth Embodiment

There is a possibility where the etching rate is locally reduced in a part of the substrate 2 depending on the mask open area ratio and the aspect ratio of the etching shape in the etching process of the substrate 2. In detail, in a case of a great mask open area ratio (e.g., not smaller than 10%), a case of a high aspect ratio (e.g., not lower than five) or in a similar case, a larger amount of reaction products are generated during the etching reaction. Then, the gas containing the reaction products easily stays at the center of the substrate 2, and the reaction products tend to readhere to the pattern of the substrate 2. There is a possibility where the readhesion of the reaction products causes a local etching rate reduction and causes intraplanar nonuniform processing. In this case, further importance needs to be attached to the intraplanar uniformization of the etching process than the prevention of the excessive dissociation and ionization of the etching gas described above. The tenth embodiment is the dry etching apparatus 1 constructed from the above point of view.

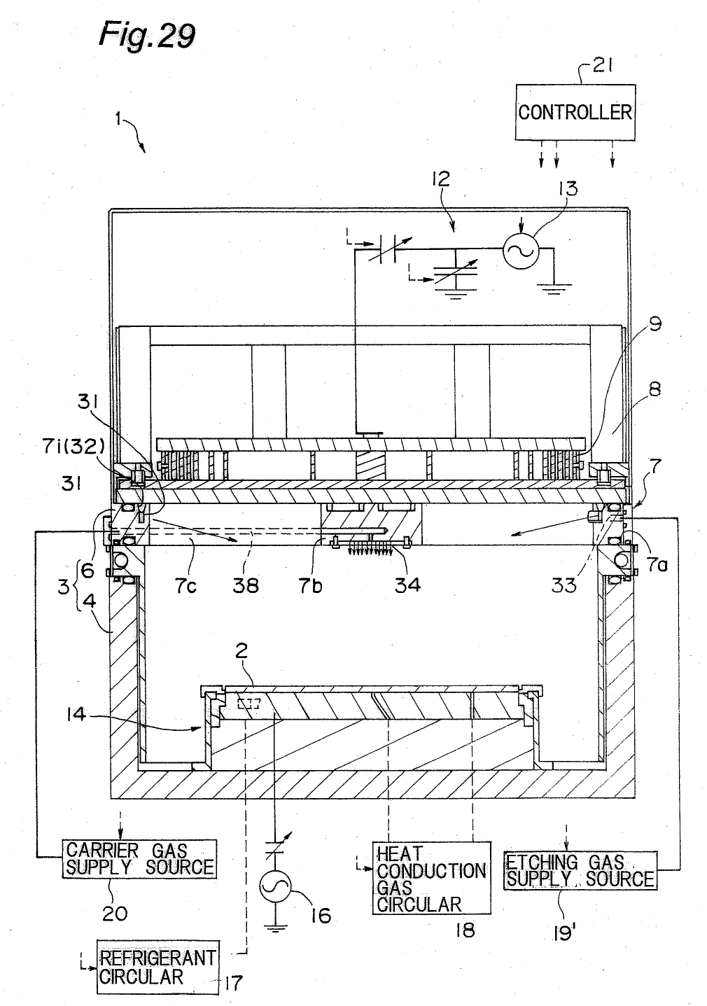

In the dry etching apparatus 1 of the tenth embodiment of the present invention shown in FIG. 29, the etching gas supply source 19′ is connected to the inlet passage 33 contrary to the ninth embodiment, and the carrier gas supply source 20 is connected to the gas passage 38. Therefore, the etching gas supplied from the etching gas supply source 19′ is obliquely downwardly ejected into the chamber 3 from the gas inlet port (first gas inlet port) 31 through the inlet passage 33 and the annular gas passage 32 and directed from the outer peripheral portion to the central portion of the substrate 2 retained on the substrate susceptor 14. Moreover, the carrier gas supplied from the carrier gas supply source 20 is downwardly ejected into the chamber 3 from the gas inlet port (second gas inlet port) 34 of the inlet port plate 36 by way of the gas passage 38, inlet gas passage 37 and gas distribution chamber 41 and directed to the central portion of the substrate 2 retained on the substrate susceptor 14.

In the present embodiment, by ejecting the carrier gas from the second gas inlet port 34 while ejecting the etching gas obliquely downwardly from the first gas inlet ports 31 formed at the outer peripheral portion 7a of the beam-shaped spacer 7 to thereby generate high-density radicals and ions, the discharge of the etching gas and the reaction products at the center of the substrate 2 is promoted to allow the flow rate distribution to be uniformized. As a result, a uniform etching process free of nonuniformity of the etching rate and so on in the entire substrate can be performed without increasing or decreasing the flow rate of the process gas that contributes to the etching characteristics such as etching rate, etching shape and so on. In this case, it should be noted that the statement of “without increasing or decreasing the flow rate of the process gas” does not mean elimination of an increase or decrease in the flow rate of the process gas to an extent that no bad influence is exerted on the etching characteristics.

In the ninth and tenth embodiments described above, the etching gas is ejected from either one of the first and second gas inlet ports 31 and 34, and the carrier gas is ejected from the other one. However, the etching gas may be ejected from both of the first and second gas inlet ports 31 and 34 by the etching gas supply source 19′. Moreover, the carrier gas may be ejected from either one or both of the first and second gas inlet ports 31 and 34 by the carrier gas supply source 20 regardless of whether the etching gases is ejected from either one of the first and second gas inlet ports 31 and 34 or ejected from both of them.

As described above, in the case of a great mask open area ratio (e.g., not smaller than 10%), the case of a high aspect ratio (e.g., not lower than five) or in a similar case, gas containing the reaction products generated during the etching reaction stays at the center of the substrate 2, and the reaction products tend to readhere to the pattern at the center of the substrate 2. This locally reduces the etching rate at the center of the substrate 2. Moreover, when the mask open area ratio is larger (e.g., 30%), a larger amount of reaction products tend to be generated and readhere to the inside of the pattern at the peripheral portion of the substrate 2. This locally reduces the etching rate at the peripheral portion of the substrate 2.

However, by ejecting the carrier gas at an appropriate flow rate from one or both of the first and second gas inlet ports 31 and 34, the stay of the gas on the substrate 2 can be improved. This eliminates the local reduction in the etching rate and uniformizes the etching process on the substrate 2. In this case, it is unnecessary to increase or decrease the flow rate of the etching gas that contributes to the etching characteristics such as etching rate, etching shape and so on. In other words, by ejecting the carrier gas at an appropriate flow rate from at least one of the first and second gas inlet ports 31 and 34, the etching process on the substrate 2 can be uniformized without changing the flow rate of the process gas that greatly contributes to the etching characteristics. In this case, it should be noted that the statement of “without increasing or decreasing the flow rate of the process gas” does not mean elimination of an increase or decrease in the flow rate of the process gas to an extent that no bad influence is exerted on the etching characteristics.

Although the present invention has been described taking the dry etching processing apparatus of the ICP type as an example, the present invention can also be applied to other plasma processing apparatuses such as plasma CVD apparatuses.

Although the present invention has been fully described in connection with the preferred embodiments thereof with reference to the accompanying drawings, various modifications and corrections are apparent to those skilled in the art. It should be recognized that such modifications and corrections are included within the scope of the present invention unless they depart from the scope of the present invention specified by the appended claims.

The entire disclosures of the specifications, drawings and claims of Japanese Patent Application No. 2005-319575 filed on Nov. 2, 2005, Japanese Patent Application No. 2005-329756 filed on Nov. 15, 2005, and Japanese Patent Application No. 2006-275409 filed on Oct. 6, 2006, are incorporated by reference into the present specification.

1-20. (canceled)

21. A plasma processing apparatus, comprising:
a vacuum vessel in which a substrate is placed;
a beam-shaped structure placed at an upper opening of the vacuum vessel opposed to the substrate and provided with an annular outer peripheral portion a lower surface of which is supported by the vacuum vessel, a central portion located at a center of a region surrounded by the outer peripheral portion in plane view, and a plurality of beam portions which extend radially from the central portion to the outer peripheral portion, a region surrounded by the outer peripheral portion, the central portion and the beam portions constituting a window portions;
a dielectric plate a lower surface of which is supported by an upper surface of the beam-shaped structure;—
a coil for generating plasma which is placed on an upper surface side of the dielectric plate and to which a high-frequency power is applied;
an elastic member interposed between the upper surface of the beam-shaped structure and the lower surface of the dielectric plate; and
an outer peripheral gas inlet port placed at an inner surface of the outer peripheral portion of the beam-shaped structure and obliquely downwardly oriented.

22. The plasma processing apparatus according to claim 21, wherein the elastic member is accommodated in a groove formed on the upper surface of the beam-shaped structure.

23. The plasma processing apparatus according to claim 21, wherein the radially extending plurality of beam portions of the beam-shaped structure extend perpendicularly to a conductor that constitutes the coil in plane view.

24. The plasma processing apparatus according to claim 21, wherein the dielectric plate has a disk-like shape, and
wherein the beam-shaped structure is provided with the outer peripheral portion of an annular shape and the beam portion of a rectangular shape with a constant width.

25. The plasma processing apparatus according to claim 21, further comprising
a gas supply passage at least partially formed in the beam-shaped structure and supplying a process gas from a process gas supply source to the outer peripheral gas inlet port so as to be ejected into the vacuum vessel.

26. The plasma processing apparatus according to claim 25, wherein the gas supply passage is formed in the outer peripheral portion of the beam-shaped structure and comprises an annular gas passage that has an inner peripheral wall side communicating with the outer peripheral gas inlet port and an outer peripheral wall side communicating with the process gas supply source side, and
wherein the apparatus further comprises a partition wall provided in the annular gas passage so as to partition inside of the annular gas passage into a discharge space located on the inner peripheral wall side and a supply space located on the outer peripheral wall side and formed with a plurality of communication holes at intervals for communication between the discharge space and the supply space.

27. The plasma processing apparatus according to claim 25, further comprising an outer peripheral side inlet port member replaceably attached to the outer peripheral portion of the beam-shaped structure and formed with the outer peripheral gas inlet port.

28. The plasma processing apparatus according to claim 25, wherein the central portion of the beam-shaped structure is located above the central portion of the substrate, and
wherein the apparatus further comprises a central gas inlet port arranged at the central portion of the beam-shaped structure for ejecting the process gas supplied from the process gas supply source via the gas passage downwardly toward the central portion of the substrate.

29. The plasma processing apparatus according to claim 28, further comprising a central inlet port member replaceably attached to a lower surface of the central portion of the beam-shaped structure and formed with the central gas inlet port.

30. The plasma processing apparatus according to claim 25, further comprising a beam portion gas inlet port arranged at a lower surface of the beam portion of the beam-shaped structure for ejecting the process gas supplied from the process gas supply source via the gas passage downwardly toward the substrate.

31. The plasma processing apparatus according to claim 21, comprising a cooling mechanism for cooling the beam-shaped structure and the dielectric plate.

32. The plasma processing apparatus according to claim 31, wherein the cooling mechanism comprises a refrigerant passage formed in the beam-shaped structure and a refrigerant circulator circulating a temperature-controlled refrigerant in the refrigerant passage.

33. The plasma processing apparatus according to claim 21, further comprising:
a central gas inlet port formed at the central portion of the beam-shaped structure and downwardly ejecting a gas toward the central portion of the substrate;
a carrier gas supply source capable of ejecting a carrier gas from at least one of the outer peripheral gas inlet port and the central gas inlet port; and
a process gas supply source capable of ejecting a process gas from at least one of the outer peripheral gas inlet port and the central gas inlet port.

34. The plasma processing apparatus according to claim 33, wherein the carrier gas supply source ejects the carrier gas from the outer peripheral gas inlet port, and
wherein the process gas supply source ejects the process gas from the central gas inlet port.

35. The plasma processing apparatus according to claim 33, wherein the process gas supply source ejects the process gas from the outer peripheral gas inlet port, and
wherein the carrier gas supply source ejects the carrier gas from the central gas inlet port.
